(19) United States
(12) Patent Application Publication
(10) Pub. No.: US 2025/0311559 A1
(43) Pub. Date: Oct. 2, 2025

(54) DISPLAY DEVICE, METHOD FOR MANUFACTURING THE DISPLAY DEVICE, AND HEAD MOUNT DISPLAY INCLUDING THE DISPLAY DEVICE

(71) Applicant: Samsung Display Co., Ltd., Yongin-si (KR)

(72) Inventor: Chun Gi YOU, Yongin-si (KR)

(21) Appl. No.: 19/090,185

(22) Filed: Mar. 25, 2025

(30) Foreign Application Priority Data
Mar. 27, 2024 (KR) 10-2024-0041500

(51) Int. Cl. H10K 59/122; G02B 27/01; H10K 59/12; H10K 102/00

(52) U.S. Cl. CPC H10K 59/122; G02B 27/0172; H10K 59/1201; G02B 2027/0178; H10K 2102/351

(57) ABSTRACT

A display device includes: a substrate; an insulating film on the substrate; a first electrode on the insulating film; a residual film on an edge of an upper surface of the first electrode; a first pixel defining film on a side surface of the first electrode and a side surface of the residual film; a second pixel defining film on the residual film and the first pixel defining film; a trench penetrating through the first pixel defining film and the second pixel defining film; a light emitting stack on the upper surface of the first electrode and the second pixel defining film; and a second electrode on the light emitting stack.

### CROSS-REFERENCE TO RELATED APPLICATION

The present application claims priority to and the benefit of Korean Patent Application No. 10-2024-0041500, filed on Mar. 27, 2024, in the Korean Intellectual Property Office, the entire disclosure of which is incorporated by reference herein.

### BACKGROUND

### 1. Field

Aspects of one or more embodiments of the present disclosure relate to a display device, a method for manufacturing the display device, and a head mounted display including the display device.

### 2. Description of the Related Art

A head mounted display (HMD) is an image display device that is worn on a user's head in the form of glasses or a helmet, and forms a focus at a distance close to a front of a user's eyes. The head mounted display may implement virtual reality (VR) or augmented reality (AR).

The head mounted display magnifies and displays an image displayed by a small display device using a plurality of lenses. Therefore, a display device applied to the head mounted display may provide a high-resolution image, for example, such as an image having a resolution of 3,000 pixels per inch (PPI) or more. Accordingly, an organic light emitting diode on silicon (OLEDoS), which is a small organic light emitting display device having a high resolution, has been used as the display device applied to the head mounted display. The OLEDoS is a device that displays an image by disposing organic light emitting diodes (OLEDs) on a semiconductor wafer substrate including complementary metal oxide semiconductors (CMOSs).

The above information disclosed in this Background section is for enhancement of understanding of the background of the present disclosure, and therefore, it may contain information that does not constitute prior art.

### SUMMARY

Some embodiments of the present disclosure may be directed to a display device capable of providing a high-resolution image.

Some embodiments of the present disclosure may be directed to a method for manufacturing a display device capable of providing a high-resolution image.

However, the present disclosure is not limited to the above aspects and features. The above and other aspects and features of the present disclosure will become more apparent to those having ordinary skill in the art by referencing the description below.

According to one or more embodiments of the present disclosure, a display device includes: a substrate; an insulating film on the substrate; a first electrode on the insulating film; a residual film on an edge of an upper surface of the first electrode; a first pixel defining film on a side surface of the first electrode and a first side surface of the residual film; a second pixel defining film on the residual film and the first pixel defining film; a trench penetrating through the first pixel defining film and the second pixel defining film; a light emitting stack on the upper surface of the first electrode and the second pixel defining film; and a second electrode on the light emitting stack.

In some embodiments, a sum of a thickness of the first electrode and a thickness of the residual film may be the same as a thickness of the first pixel defining film.

In some embodiments, a thickness of the residual film may be smaller than a thickness of the first electrode.

In some embodiments, an upper surface of the residual film and an upper surface of the first pixel defining film may be connected to each other to be flat.

In some embodiments, the first side surface of the residual film and the side surface of the first electrode may be connected to each other to be flat.

In some embodiments, a second side surface of the residual film opposite to the first side surface of the residual film and one side surface of the second pixel defining film may be connected to each other to be flat.

In some embodiments, the light emitting stack may be located on the second side surface of the residual film and the one side surface of the second pixel defining film.

In some embodiments, the residual film may include a different material from those of the first pixel defining film and the second pixel defining film.

In some embodiments, the residual film may include silicon nitride, and each of the first pixel defining film and the second pixel defining film may include silicon oxide.

In some embodiments, a thickness of the first pixel defining film may be greater than a thickness of the second pixel defining film.

In some embodiments, a width of the second pixel defining film located between the first electrode and another first electrode adjacent to the first electrode may be greater than a width of the first pixel defining film.

In some embodiments, the display device may further include a third pixel defining film on the second pixel defining film.

In some embodiments, a thickness of the first pixel defining film may be greater than a thickness of the third pixel defining film.

In some embodiments, a width of the third pixel defining film located between the first electrode and another first electrode adjacent to the first electrode may be greater than a width of the first pixel defining film.

In some embodiments, a width of the first pixel defining film located between the first electrode and another first electrode adjacent to the first electrode may be greater than a width of the third pixel defining film.

In some embodiments, the first pixel defining film may be located on the residual film.

According to one or more embodiments of the present disclosure, a method for manufacturing a display device, includes: sequentially forming a first electrode layer and a protective layer on a substrate; forming first electrodes and protective films respectively disposed on the first electrodes by forming a first mask pattern on the protective layer, and etching the first electrode layer and the protective layer using the first mask pattern as a mask; removing the first mask pattern and forming a first pixel defining layer covering the protective films; forming a first pixel defining film between the first electrodes and the protective layer by removing the first pixel defining layer through a polishing process; forming a second pixel defining layer on the protective films and the first pixel defining film; forming a second pixel defining film by forming a second mask pattern on the second pixel defining layer, and etching the second pixel defining layer using the second mask pattern as a mask; and exposing a portion of an upper surface of each of the first electrodes by removing the second mask pattern, and etching the protective layers using the second pixel defining film as a mask.

In some embodiments, in the exposing of the portion of the upper surface of each of the first electrodes, residual films formed by etching the protective films may be disposed on an edge of the upper surface of the first electrodes, respectively.

In some embodiments, the method may further include forming trenches penetrating through the first pixel defining film and the second pixel defining film after the exposing of the portion of the upper surface of each of the first electrodes.

In some embodiments, the method may further include, after the forming of the trenches, forming a light emitting stack covering the portion of the upper surface of each of the first electrodes and the second pixel defining film, forming a second electrode on the light emitting stack, and forming an encapsulation layer covering the second electrode.

According to one or more embodiments of the present disclosure, a head mounted display includes: at least one display device; a display device housing configured to house the at least one display device; and an optical member configured to magnify a display image of the at least one display device, or convert an optical path. The at least one display device includes: a substrate; an insulating film on the substrate; a first electrode on the insulating film; a residual film on an edge of an upper surface of the first electrode; a first pixel defining film on a side surface of the first electrode and a side surface of the residual film; a second pixel defining film on the residual film and the first pixel defining film; a trench penetrating through the first pixel defining film and the second pixel defining film; a light emitting stack on the upper surface of the first electrode and the second pixel defining film; and a second electrode on the light emitting stack.

According to some embodiments of the present disclosure, by forming a protective film on an upper surface of a first electrode, it may be possible to prevent or substantially prevent the first electrode from being etched in a process of etching a pixel defining film to form emission areas. According to some embodiments of the present disclosure, it may be possible to prevent or substantially prevent the first electrode from being oxidized by oxygen (O₂) in an ashing process for removing a mask pattern formed to pattern the pixel defining film.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is an exploded perspective view illustrating a display device according to an embodiment;

FIG. 2 is a block diagram illustrating the display device according to an embodiment;

FIG. 3 is an equivalent circuit diagram of a first sub-pixel according to an embodiment;

FIG. 4 is a layout diagram illustrating an example of a display panel according to an embodiment;

FIGS. 5 and 6 are layout diagrams illustrating some embodiments of a display area of FIG. 4;

FIG. 7 is a cross-sectional view illustrating an example of the display panel taken along the line I1-I1′ of FIG. 5;

FIG. 8A is a cross-sectional view illustrating an example of the area A1 of FIG. 7 in more detail;

FIG. 8B is a cross-sectional view illustrating another example of the area A1 of FIG. 7 in more detail;

FIG. 9 is a flowchart illustrating a method for manufacturing a display panel according to an embodiment;

FIGS. 10-17 are cross-sectional views illustrating a method for manufacturing a display panel according to an embodiment corresponding to the area A1 in FIG. 7 in more detail;

FIG. 18 is a perspective view illustrating a head mounted display according to an embodiment;

FIG. 19 is an exploded perspective view illustrating an example of the head mounted display of FIG. 18; and

FIG. 20 is a perspective view illustrating a head mounted display according to another embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Additionally, the use of cross-hatching and/or shading in the accompanying drawings is generally provided to indicate boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, and/or the like of the elements, unless otherwise specified.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

For example, an implanted region illustrated as a rectangle may have rounded or curved features and/or a gradient of implant concentration at its edges, rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device, and thus, are not intended to be limiting.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

As used herein, the phrases “on a plane” and “in a plan view” refer to a view of a target portion from the top, and the phrases “on a cross-section” and “in a cross-sectional view) refers to a view of a cross-section formed by vertically cutting a target portion from the side.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), or formed on one substrate. Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the spirit and scope of the example embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

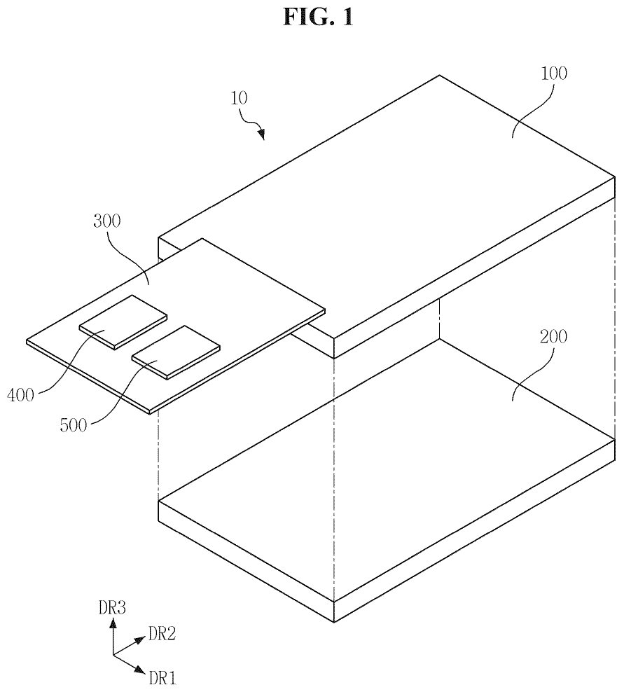

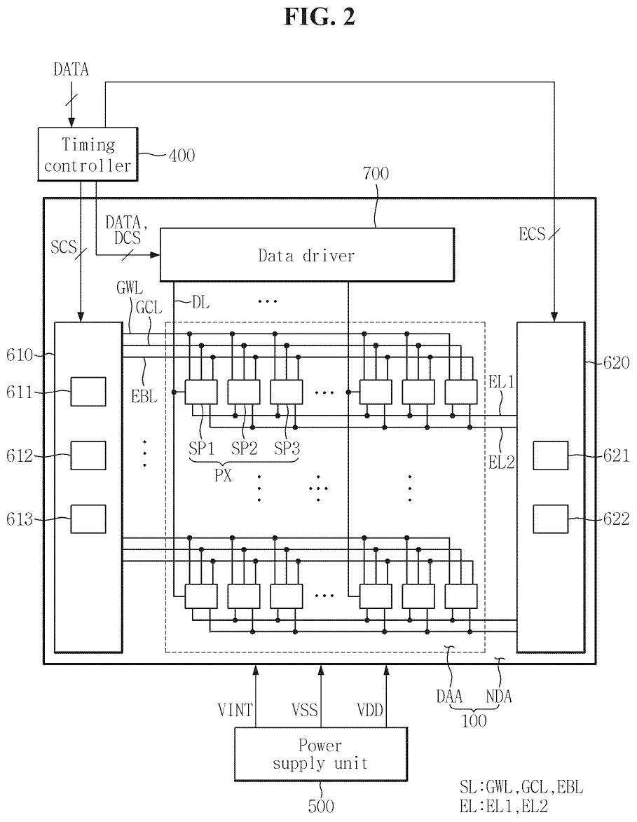

FIG. 1 is an exploded perspective view illustrating a display device according to an embodiment. FIG. 2 is a block diagram illustrating the display device according to an embodiment.

Referring to FIGS. 1 and 2, a display device 10 according to an embodiment is a device that displays a moving image and/or a still image. The display device 10 according to an embodiment may be applied to various suitable portable electronic devices, such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according an embodiment may be applied as a display unit (e.g., a display, a display screen, a display layer, or a display panel) of televisions, laptop computers, monitors, billboards, or the Internet of Things (IoT) devices. As another example, the display device 10 according an embodiment may be applied to smart watches, watch phones, or head mounted displays (HMDs) for implementing virtual reality and/or augmented reality.

The display device 10 according to an embodiment includes a display panel 100, a heat dissipation layer 200, a circuit board 300, a timing controller 400, and a power supply unit (e.g., a power supply) 500.

The display panel 100 may have a shape similar to a rectangular shape in a plan view. For example, the display panel 100 may have short sides extending in a first direction DR1, and long sides extending in a second direction DR2 crossing the first direction DR1. In the display panel 100, a corner where the short side extending in the first direction DR1 and the long side extending in the second direction DR2 meet each other may be rounded with a curvature (e.g., a predetermined curvature), or may be right-angled. A shape of the display panel 100 in a plan view is not limited to that similar to the rectangular shape, and may be a shape similar to other polygonal shapes, a circular shape, or an elliptical shape. A shape of the display device 10 in a plan view may follow the shape of the display panel 100 in a plan view, but the present disclosure is not limited thereto.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA that displays an image, and a non-display area NDA that does not display an image, as illustrated in FIG. 2.

The plurality of pixels PX may be arranged in the display area DAA. The plurality of pixels PX may be arranged in a matrix form along the first direction DR1 and the second direction DR2. The plurality of scan lines SL and the plurality of emission control lines EL may extend in the first direction DR1, and may be disposed along the second direction DR2. The plurality of data lines DL may extend in the second direction DR2, and may be disposed along the first direction DR1.

The plurality of scan lines SL may include a plurality of write scan lines GWL, a plurality of control scan lines GCL, and a plurality of bias scan lines EBL. The plurality of emission control lines EL include a plurality of first emission control lines EL1 and a plurality of second emission control lines EL2.

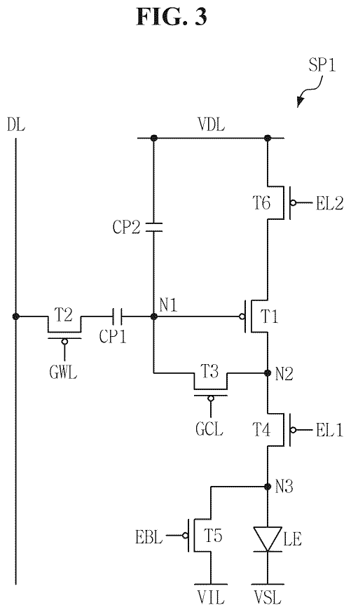

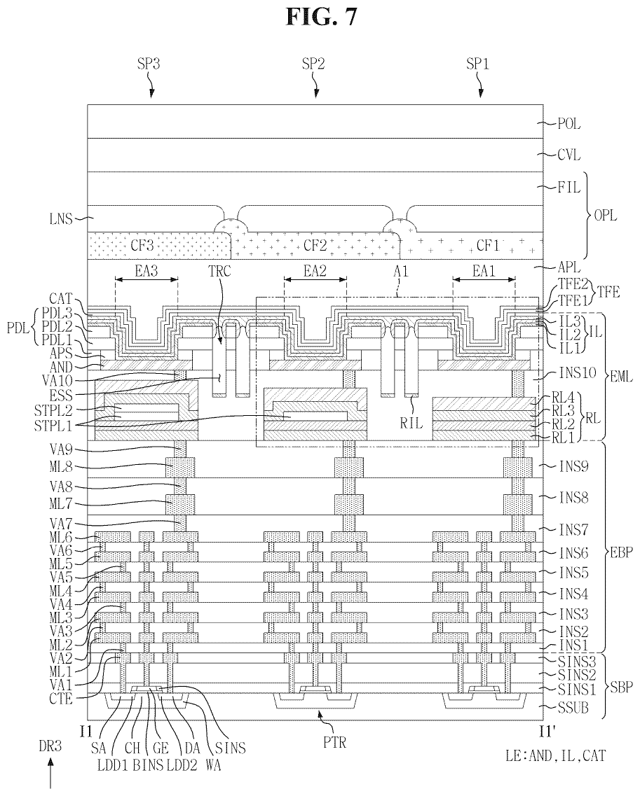

Each of the plurality of pixels PX includes a plurality of sub-pixels SP1, SP2, and SP3. The plurality of sub-pixels SP1, SP2, and SP3 may include a plurality of pixel transistors as illustrated in FIG. 3, and the plurality of pixel transistors may be formed by a semiconductor process and disposed on a semiconductor substrate SSUB (e.g., see FIG. 7). For example, a plurality of pixel transistors of the data driver 700 may be formed as complementary metal oxide semiconductors (CMOSs), but the present disclosure is not limited thereto.

Each of the plurality of sub-pixels SP1, SP2, and SP3 may be connected to any one of the plurality of write scan lines GWL, any one of the plurality of control scan lines GCL, any one of the plurality of bias scan lines EBL, any one of the plurality of first emission control lines EL1, any one of the plurality of second emission control lines EL2, and any one of the plurality of data lines DL. Each of the plurality of sub-pixels SP1, SP2, and SP3 may receive a data voltage of the corresponding data line DL according to a write scan signal of the corresponding write scan line GWL, and may allow a light emitting element to emit light according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed by a semiconductor process on a semiconductor substrate SSUB (e.g., see FIG. 7). For example, the plurality of scan transistors and the plurality of light emitting transistors may be formed as CMOSs, but the present disclosure is not limited thereto.

The scan driver 610 may include a write scan signal output unit (e.g., a write scan signal output circuit) 611, a control scan signal output unit (e.g., a control scan signal output circuit) 612, and a bias scan signal output unit (e.g., a bias scan signal output circuit) 613. Each of the write scan signal output unit 611, the control scan signal output unit 612, and the bias scan signal output unit 613 may receive a scan timing control signal SCS from the timing controller 400. The write scan signal output unit 611 may generate write scan signals according to the scan timing control signal SCS of the timing controller 400, and may sequentially output the write scan signals to the write scan lines GWL. The control scan signal output unit 612 may generate control scan signals according to the scan timing control signal SCS, and may sequentially output the control scan signals to the control scan lines GCL. The bias scan signal output unit 613 may generate bias scan signals according to the scan timing control signal SCS, and may sequentially output the bias scan signals to the bias scan lines EBL.

The emission driver 620 includes a first emission control driver 621 and a second emission control driver 622. Each of the first emission control driver 621 and the second emission control driver 622 may receive an emission timing control signal ECS from the timing controller 400. The first emission control driver 621 may generate first emission control signals according to the emission timing control signal ECS, and may sequentially output the first emission control signals to the first emission control lines EL1. The second emission control driver 622 may generate second emission control signals according to the emission timing control signal ECS, and may sequentially output the second emission control signals to the second emission control lines EL2.

The data driver 700 may include a plurality of data transistors, and the plurality of data transistors may be formed by a semiconductor process on a semiconductor substrate SSUB (e.g., see FIG. 7). For example, the plurality of data transistors may be formed as CMOSs, but the present disclosure is not limited thereto.

The data driver 700 may receive digital video data DATA and a data timing control signal DCS from the timing controller 400. The data driver 700 converts the digital video data DATA into analog data voltages according to the data timing control signal DCS, and outputs the analog data voltages to the data lines DL. In this case, the sub-pixels SP1, SP2, and SP3 may be selected by the write scan signals of the scan driver 610, and the data voltages may be supplied to the selected sub-pixels SP1, SP2, and SP3.

The heat dissipation layer 200 may overlap with the display panel 100 in a third direction DR3, which is the thickness direction of the display panel 100. The heat dissipation layer 200 may be disposed on one surface of the display panel 100, for example, such as the rear surface of the display panel 100. The heat dissipation layer 200 serves to dissipate heat generated from the display panel 100. The heat dissipation layer 200 may include a layer including (e.g., made of) graphite or a metal, such as silver (Ag), copper (Cu), or aluminum (Al), having a high thermal conductivity.

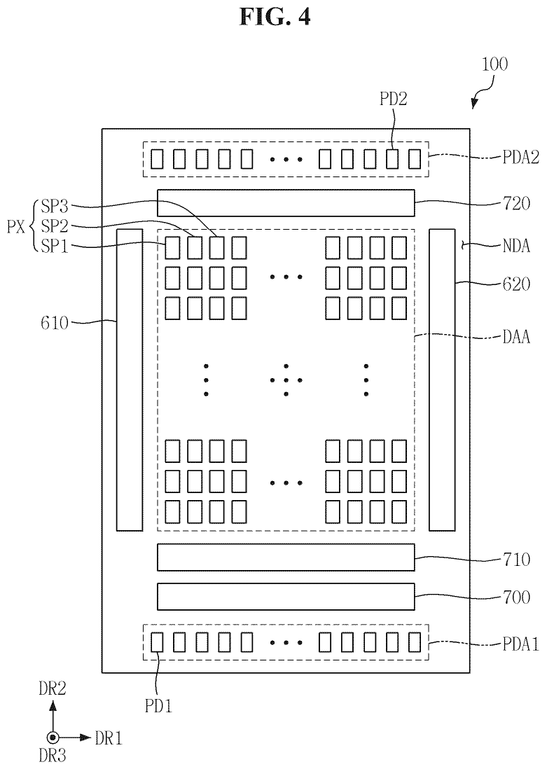

The circuit board 300 may be electrically connected to a plurality of first pads PD1 (e.g., see FIG. 4) of a first pad unit (e.g., a first pad area or terminal) PDA1 of the display panel 100 using a conductive adhesive member, such as an anisotropic conductive film. The circuit board 300 may be a flexible printed circuit board or a flexible film having a flexible material. FIG. 1 illustrates that the circuit board 300 is unbent, but the circuit board 300 may be bent. In this case, one end of the circuit board 300 may be disposed on the rear surface of the display panel 100 and/or the rear surface of the heat dissipation layer 200. Another end (e.g., an opposite end) of the circuit board 300 may be connected to the plurality of first pads PD1 (e.g., see FIG. 4) of the first pad unit PDA1 of the display panel 100 using the conductive adhesive member. The one end of the circuit board 300 and the other end of the circuit board 300 may be opposite ends from each other.

The timing controller 400 may receive digital video data DATA and timing signals from the outside. The timing controller 400 may generate the scan timing control signal SCS, the emission timing control signal ECS, and the data timing control signal DCS for controlling the display panel 100 according to the timing signals. The timing controller 400 may output the scan timing control signal SCS to the scan driver 610, and may output the emission timing control signal ECS to the emission driver 620. The timing controller 400 may output the digital video data DATA and the data timing control signal DCS to the data driver 700.

The power supply unit 500 may generate a plurality of panel driving voltages according to an external source voltage. For example, the power supply unit 500 may generate a first driving voltage VSS, a second driving voltage VDD, and a third driving voltage VINT, and may supply the first driving voltage VSS, the second driving voltage VDD, and the third driving voltage VINT to the display panel 100. The first driving voltage VSS, the second driving voltage VDD, and the third driving voltage VINT will be described in more detail below with reference to FIG. 3.

Each of the timing controller 400 and the power supply unit 500 may be formed as an integrated circuit (IC), and may be attached to one surface of the circuit board 300. In this case, the scan timing control signal SCS, the emission timing control signal ECS, the digital video data DATA, and the data timing control signal DCS of the timing controller 400 may be supplied to the display panel 100 through the circuit board 300. In addition, the first driving voltage VSS, the second driving voltage VDD, and the third driving voltage VINT of the power supply unit 500 may be supplied to the display panel 100 through the circuit board 300.

As another example, each of the timing controller 400 and the power supply unit 500 may be disposed in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process on a semiconductor substrate SSUB (e.g., see FIG. 7). For example, the plurality of timing transistors and the plurality of power transistors may be formed as CMOSs, but the present disclosure is not limited thereto. Each of the timing controller 400 and the power supply unit 500 may be disposed between the data driver 700 and the first pad unit PDA1 (e.g., see FIG. 4).

FIG. 3 is an equivalent circuit diagram of a first sub-pixel according to an embodiment.

Referring to FIG. 3, a first sub-pixel SP1 may be connected to a write scan line GWL, a control scan line GCL, a bias scan line EBL, a first emission control line EL1, a second emission control line EL2, and a data line DL. In addition, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. In other words, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than that of the third driving voltage VINT. The second driving voltage VDD may be a voltage higher than that of the third driving voltage VINT.

The first sub-pixel SP1 includes a plurality of transistors T1 to T6, a light emitting element LE, a first capacitor CP1, and a second capacitor CP2.

The light emitting element LE emits light according to a driving current Ids flowing through a channel of the first transistor T1. An amount of light emitted from the light emitting element LE may be proportional to the driving current Ids. The light emitting element LE may be disposed between the fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode electrode, and the second electrode of the light emitting element LE may be a cathode electrode. The light emitting element LE may be an organic light emitting diode including the first electrode, the second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, and in this case, the light emitting element LE may be a micro light emitting diode.

The first transistor T1 may be a driving transistor for controlling a source-drain current Ids (hereinafter referred to as a “driving current”) flowing between the source electrode and the drain electrode thereof according to a voltage applied to a gate electrode thereof. The first transistor T1 includes the gate electrode connected to a first node N1, the source electrode connected to a drain electrode of the sixth transistor T6, and the drain electrode connected to a second node N2.

The second transistor T2 may be disposed between one electrode of the first capacitor CP1 and the data line DL. The second transistor T2 is turned on by a write scan signal of the write scan line GWL to connect the one electrode of the first capacitor CP1 to the data line DL. As such, a data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by a control scan signal of the control scan line GCL to connect the first node N1 to the second node N2. As such, the gate electrode and the drain electrode of the first transistor T1 may be connected to each other, and thus, the first transistor T1 may operate like a diode (e.g., the first transistor T1 may be diode-connected). The third transistor T3 includes a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 to connect the second node N2 to the third node N3. As such, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

The fifth transistor T5 may be disposed between the third node N3 and the third driving voltage line VIL. The fifth transistor T5 is turned on by a bias scan signal of the bias scan line EBL to connect the third node N3 to the third driving voltage line VIL. As such, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by a second emission control signal of the second emission control line EL2 to connect the source electrode of the first transistor T1 to the second driving voltage line VDL. As such, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes the one electrode connected to the drain electrode of the second transistor T2 and another electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and another electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first to sixth transistors T1 to T6 may be a metal oxide semiconductor field effect transistor (MOSFET). For example, each of the first to sixth transistors T1 to T6 may be a P-type MOSFET, but the present disclosure is not limited thereto. As another example, each of the first to sixth transistors T1 to T6 may be an N-type MOSFET. As another example, some of the first to sixth transistors T1 to T6 may be P-type MOSFETs, and the others of the first to sixth transistors T1 to T6 may be N-type MOSFETs.

While FIG. 3 illustrates that the first sub-pixel SP1 includes six transistors T1 to T6 and two capacitors C1 and C2, the present disclosure is not limited to the equivalent circuit diagram of the first sub-pixel SP1 described above with reference to FIG. 3. For example, the numbers of the transistors and the capacitors of the first sub-pixel SP1 may be variously modified as needed or desired as would be understood by those having ordinary skill in the art.

In addition, the equivalent circuit diagram of the second sub-pixel SP2 and the equivalent circuit diagram of the third sub-pixel SP3 may be the same or substantially the same as the equivalent circuit diagram of the first sub-pixel SP1 described above with reference to FIG. 3. Therefore, redundant description with respect to the equivalent circuit diagram of the second sub-pixel SP2 and the equivalent circuit diagram of the third sub-pixel SP3 may not be repeated.

FIG. 4 is a layout diagram illustrating an example of a display panel according to an embodiment.

Referring to FIG. 4, the display area DAA of the display panel 100 according to an embodiment includes a plurality of pixels PX arranged in a matrix form. The non-display area NDA of the display panel 100 according to an embodiment includes a scan driver 610, an emission driver 620, a data driver 700, a first distribution circuit 710, a second distribution circuit 720, a first pad unit (e.g., a first pad area or terminal) PDA1, and a second pad unit (e.g., a second pad area or terminal) PDA2.

The scan driver 610 may be disposed on a first side of the display area DAA. The emission driver 620 may be disposed on a second side of the display area DAA. For example, the scan driver 610 may be disposed on one side of the display area DAA in the first direction DR1, and the emission driver 620 may be disposed on another side (e.g., an opposite side) of the display area DAA in the first direction DR1. In other words, the scan driver 610 may be disposed on the left side of the display area DAA, and the emission driver 620 may be disposed on the right side of the display area DAA. However, the present disclosure is not limited thereto, and scan drivers 610 and emission drivers 620 may be disposed on both the first and second sides of the display area DAA.

The first pad unit PDA1 may include a plurality of first pads PD1 connected to pads or bumps of the circuit board 300 through a conductive adhesive member. The first pad unit PDA1 may be disposed on a third side of the display area DAA. For example, the first pad unit PDA1 may be disposed on one side of the display area DAA in the second direction DR2. The first pad unit PDA1 may be disposed outside the data driver 700 in the second direction DR2. In other words, the first pad unit PDA1 may be disposed closer to an edge of the display panel 100 than (e.g., when compared to) the data driver 700.

The second pad unit PDA2 may include a plurality of second pads PD2 corresponding to inspection pads for inspecting whether or not the display panel 100 operates normally. The plurality of second pads PD2 may be connected to a jig or a probe pin, or may be connected to a circuit board for inspection in an inspection process. The circuit board for inspection may be a printed circuit board including (e.g., made of) a rigid material, or a flexible printed circuit board including (e.g., made of) a flexible material.

The second pad unit PDA2 may be disposed on a fourth side of the display area DAA. For example, the second pad unit PDA2 may be disposed on another side (e.g., an opposite side) of the display area DAA in the second direction DR2. The second pad unit PDA2 may be disposed outside the second distribution circuit 720 in the second direction DR2. In other words, the second pad unit PDA2 may be disposed closer to an edge of the display panel 100 than (e.g., when compared to) the second distribution circuit 720.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (where P is a positive integer of 2 or more), and as such, the number of first pads PD1 may be reduced. The first distribution circuit 710 may be disposed on the third side of the display area DAA of the display panel 100. For example, the first distribution circuit 710 may be disposed on one side of the display area DAA in the second direction DR2. In other words, the first distribution circuit 710 may be disposed on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be disposed on the fourth side of the display area DAA of the display panel 100. For example, the second distribution circuit 720 may be disposed on another side (e.g., an opposite side) of the display area DAA in the second direction DR2. In other words, the second distribution circuit 720 may be disposed on the upper side of the display area DAA.

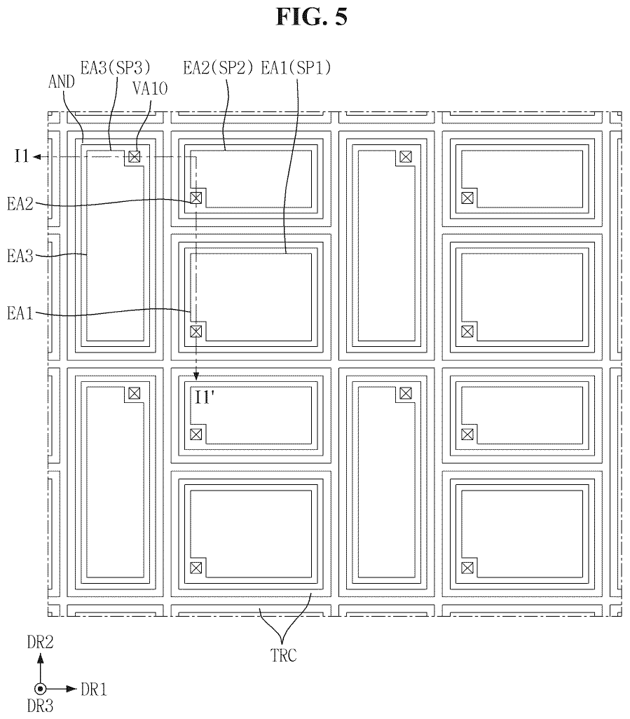

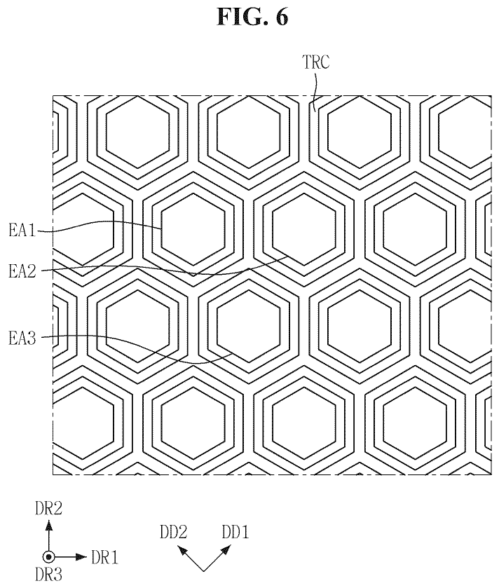

FIGS. 5 and 6 are layout diagrams illustrating some embodiments of a display area of FIG. 4.

Referring to FIGS. 5 and 6, each of the plurality of pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

Each of the first emission area EA1, the second emission area EA2, and the third emission area EA3 may have a polygonal shape, a circular shape, an elliptical shape, or an irregular shape in a plan view.

Referring to FIG. 5, a maximum length of the third emission area EA3 in the first direction DR1 may be smaller than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be the same or substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be smaller than the maximum length of the third emission area EA3 in the second direction DR2.

Each of the first emission area EA1, the second emission area EA2, and the third emission area EA3 may have a hexagonal shape including six straight lines in a plan view as illustrated in FIGS. 5 and 6, but the present disclosure is not limited thereto. Each of the first emission area EA1, the second emission area EA2, and the third emission area EA3 may have polygonal shapes other than the hexagonal shape, a circular shape, an elliptical shape, or an irregular shape in a plan view.

As illustrated in FIG. 5, in each of the plurality of pixels PX, the second emission area EA2 and the third emission area EA3 may neighbor (e.g., may be adjacent to) each other in the first direction DR1. In addition, the first emission area EA1 and the third emission area EA3 may neighbor each other in the first direction DR1. In addition, the first emission area EA1 and the second emission area EA2 may neighbor each other in the second direction DR2. An area of the first emission area EA1, an area of the second emission area EA2, and an area of the third emission area EA3 may be different from each other.

As another example, as illustrated in FIG. 6, the first emission area EA1 and the second emission area EA2 may neighbor (e.g., may be adjacent to) each other in the first direction DR1. The second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2, and may refer to a direction inclined by 45° with respect to the first direction DR1 and the second direction DR2. The second diagonal direction DD2 may be a direction crossing (e.g., orthogonal to or substantially orthogonal to) the first diagonal direction DD1.

The first emission area EA1 may emit a first light, the second emission area EA2 may emit a second light, and the third emission area EA3 may emit a third light. The first light may be light of a blue wavelength band, the second light may be light of a green wavelength band, and the third light may be light of a red wavelength band. For example, the blue wavelength band may indicate that a main peak wavelength of the light is included in a wavelength band of approximately 370 nm to 460 nm. The green wavelength band may indicate that a main peak wavelength of the light is included in a wavelength band of approximately 480 nm to 560 nm. The red wavelength band may indicate that a main peak wavelength of the light is included in a wavelength band of approximately 600 nm to 750 nm.

FIGS. 5 and 6 illustrate that each of the plurality of pixels PX includes three emission areas EA1, EA2, and EA3, but the present disclosure is not limited thereto. In other words, in some embodiments, each of the plurality of pixels PX may include four emission areas.

In addition, an arrangement of the emission areas of the plurality of pixels PX is not limited to those illustrated in FIGS. 5 and 6. For example, the emission areas of the plurality of pixels PX may be disposed in a stripe structure in which the emission areas are arranged along the first direction DR1, a diamond structure (e.g., a PENTILE® structure, PENTILE® being a duly registered trademark of Samsung Display Co. Ltd.) in which the emission areas have a diamond arrangement, or a hexagonal structure in which emission areas having a hexagonal shape in a plan view are arranged (e.g., see FIG. 6).

FIG. 7 is a cross-sectional view illustrating an example of the display panel taken along the line I1-I1′ of FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described above with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be disposed in an upper surface of the semiconductor substrate SSUB. The plurality of well regions WA may be areas doped with second-type impurities. The second-type impurities may be different from the first-type impurities. For example, when the first-type impurities are p-type impurities, the second-type impurities may be n-type impurities. As another example, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH disposed between the source region SA and the drain region DA.

A bottom insulating film BINS may be disposed between a gate electrode GE and the well region WA. Side surface insulating films SINS may be disposed on side surfaces of the gate electrode GE. The side surface insulating films SINS may be disposed on the bottom insulating film BINS.

Each of the source region SA and the drain region DA may be a region doped with the first-type impurities. The gate electrode GE of the pixel transistor PTR may overlap with the well region WA in the third direction DR3. The channel region CH may overlap with the gate electrode GE in the third direction DR3. The source region SA may be disposed on one side of the gate electrode GE, and the drain region SA may be disposed on another side (e.g., an opposite side) of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than that of the source region SA due to the bottom insulating film BINS. The second low-concentration impurity region LDD2 may be a region having a lower impurity concentration than that of the drain region DA due to the bottom insulating film BINS. A distance between the source region SA and the drain region DA may be increased by the first low-concentration impurity region LDD1 and the second low-concentration impurity region LDD2. Therefore, a length of the channel region CH of each of the pixel transistors PTR may be increased, and thus, a punch-through phenomena and a hot carrier phenomena that may be caused by a shorter channel may be prevented or substantially prevented.

A first semiconductor insulating film SINS1 may be disposed on the semiconductor substrate SSUB. The first semiconductor insulating film SINS1 may be formed as a silicon carbonitride (SiCN)-based inorganic film or a silicon oxide (SiOₓ)-based inorganic film, but the present disclosure is not limited thereto.

A second semiconductor insulating film SINS2 may be disposed on the first semiconductor insulating film SINS1. The second semiconductor insulating film SINS2 may be formed as a silicon oxide (SiOₓ)-based inorganic film, but the present disclosure is not limited thereto.

The plurality of contact terminals CTE may be disposed on the second semiconductor insulating film SINS2. Each of the plurality of contact terminals CTE may be connected to any one of the gate electrode GE, the source region SA, and/or the drain region DA of a corresponding one of the pixel transistors PTR through a hole penetrating through the first semiconductor insulating film SINS1 and the second semiconductor insulating film SINS2. Each of the plurality of contact terminals CTE may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof.

A third semiconductor insulating film SINS3 may be disposed on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but the present disclosure is not limited thereto.

The semiconductor substrate SSUB may be replaced with a glass substrate or a polymer resin substrate, such as a polyimide substrate, as needed or desired. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP may include a plurality of conductive layers ML1 to ML8, a plurality of vias VA1 to VA9, and a plurality of insulating films INS1 to INS9. The plurality of insulating films INS1 to INS9 may be disposed between the first to eighth conductive layers ML1 to ML8.

The first to eighth conductive layers ML1 to ML8 may serve to implement a circuit of the first sub-pixel SP1 described above with reference to FIG. 3, by connecting the plurality of contact terminals CTE exposed from the semiconductor backplane SBP to one another. For example, when only the first to sixth transistors T1 to T6 are formed in the semiconductor backplane SBP, the connection between the first to sixth transistors T1 to T6 and the formation of the first capacitor CP1 and the second capacitor CP2 may be performed through the first to eighth conductive layers ML1 to ML8. In addition, the connection between a drain region corresponding to a drain electrode of the fourth transistor T4, a source region corresponding to a source electrode of the fifth transistor T5, and a first electrode AND of the light emitting element LE may also be performed through the first to eighth conductive layers ML1 to ML8.

A first insulating film INS1 may be disposed on the semiconductor backplane SBP. Each of first vias VA1 may penetrate through the first insulating film INS1 to be connected to the corresponding contact terminal CTE exposed from the semiconductor backplane SBP. Each of the first conductive layers ML1 may be disposed on the first insulating film INS1, and may be connected to the corresponding first via VA1.

A second insulating film INS2 may be disposed on the first insulating film INS1 and the first conductive layers ML1. Each of second vias VA2 may penetrate through the second insulating film INS2 to be connected to the corresponding exposed first conductive layer ML1. Each of the second conductive layers ML2 may be disposed on the second insulating film INS2, and may be connected to the corresponding second via VA2.

A third insulating film INS3 may be disposed on the second insulating film INS2 and the second conductive layers ML2. Each of third vias VA3 may penetrate through the third insulating film INS3 to be connected to the corresponding exposed second conductive layer ML2. Each of the third conductive layers ML3 may be disposed on the third insulating film INS3, and may be connected to the corresponding third via VA3.

A fourth insulating film INS4 may be disposed on the third insulating film INS3 and the third conductive layers ML3. Each of fourth vias VA4 may penetrate through the fourth insulating film INS4 to be connected to the corresponding exposed third conductive layer ML3. Each of the fourth conductive layers ML4 may be disposed on the fourth insulating film INS4, and may be connected to the corresponding fourth via VA4.

A fifth insulating film INS5 may be disposed on the fourth insulating film INS4 and the fourth conductive layers ML4. Each of fifth vias VA5 may penetrate through the fifth insulating film INS5 to be connected to the corresponding exposed fourth conductive layer ML4. Each of the fifth conductive layers ML5 may be disposed on the fifth insulating film INS5, and may be connected to the corresponding fifth via VA5.

A sixth insulating film INS6 may be disposed on the fifth insulating film INS5 and the fifth conductive layers ML5. Each of sixth vias VA6 may penetrate through the sixth insulating film INS6 to be connected to the corresponding exposed fifth conductive layer ML5. Each of the sixth conductive layers ML6 may be disposed on the sixth insulating film INS6, and may be connected to the corresponding sixth via VA6.

A seventh insulating film INS7 may be disposed on the sixth insulating film INS6 and the sixth conductive layers ML6. Each of seventh vias VA7 may penetrate through the seventh insulating film INS7 to be connected to the corresponding exposed sixth conductive layer ML6. Each of the seventh conductive layers ML7 may be disposed on the seventh insulating film INS7, and may be connected to the corresponding seventh via VA7.

An eighth insulating film INS8 may be disposed on the seventh insulating film INS7 and the seventh conductive layers ML7. Each of eighth vias VA8 may penetrate through the eighth insulating film INS8 to be connected to the corresponding exposed seventh conductive layer ML7. Each of the eighth conductive layers ML8 may be disposed on the eighth insulating film INS8, and may be connected to the eighth via VA8.

The first to eighth conductive layers ML1 to ML8 and the first to eighth vias VA1 to VA8 may include (e.g., may be made of) the same or substantially the same material as each other. Each of the first to eighth conductive layers ML1 to ML8 and the first to eighth vias VA1 to VA8 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. The first to eighth vias VA1 to VA8 may include (e.g., may be made of) the same or substantially the same material as each other. The first to eighth insulating films INS1 to INS8 may be formed as silicon oxide (SiOₓ)-based inorganic films, but the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same or substantially the same as each other. For example, the thickness of the first conductive layer ML1 may be approximately 1,360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1,440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1,150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the thickness of the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be the same or substantially the same as each other. For example, each of the thickness of the seventh conductive layer ML7 and the thickness of the eighth conductive layer ML8 may be approximately 9,000 Å. Each of the thickness of the seventh via VA7 and the thickness of the eighth via VA8 may be approximately 6,000 Å.

A ninth insulating film INS9 may be disposed on the eighth insulating film INS8 and the eighth conductive layers ML8. The ninth insulating film INS9 may be formed as a silicon oxide (SiOₓ)-based inorganic film, but the present disclosure is not limited thereto.

Each of ninth vias VA9 may penetrate through the ninth insulating film INS9 to be connected to the corresponding exposed eighth conductive layer ML8. Each of the ninth vias VA9 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. A thickness of the ninth via VA9 may be approximately 16,500 Å.

The display element layer EML may be disposed on the light emitting element backplane EBP. The display element layer EML may include a reflective electrode layer RL, a tenth insulating film INS10, tenth vias VA10, light emitting elements LE, a pixel defining film PDL, and a plurality of trenches TRC. Each of the light emitting elements LE may include a first electrode AND, a light emitting stack IL, and a second electrode CAT.

The reflective electrode layer RL may be disposed on the ninth insulating film INS9. The reflective electrode layer RL may include one or more reflective electrodes RL1, RL2, RL3, and/or RL4, first step layers STPL1, and a second step layer STPL2. For example, FIG. 7 illustrates that the one or more reflective electrodes RL1, RL2, RL3, and/or RL4 include first to fourth reflective electrodes RL1, RL2, RL3, and RL4, but the present disclosure is not limited thereto.

Each of the first reflective electrodes RL1 may be disposed on the ninth insulating film INS9, and may be connected to the corresponding ninth via VA9. Each of the first reflective electrodes RL1 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. For example, each of the first reflective electrodes RL1 may include titanium nitride (TiN).

Each of the second reflective electrodes RL2 may be disposed on the corresponding first reflective electrode RL1. Each of the second reflective electrodes RL2 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. For example, each of the second reflective electrodes RL2 may include aluminum (Al).

In the second sub-pixel SP2 and the third sub-pixel SP3, the first step layers STPL1 may be disposed on the corresponding second reflective electrodes RL2. In the first sub-pixel SP1, the first step layer STPL1 may not be disposed on the corresponding second reflective electrode RL2.

In the third sub-pixel SP3, the second step layer STPL2 may be disposed on the corresponding first step layer STPL1. In the first sub-pixel SP1, the second step layer STPL2 may not be disposed on the corresponding second reflective electrode RL2. In addition, in the second sub-pixel SP2, the second step layer STPL2 may not be disposed on the corresponding first step layer STPL1.

A thickness of the first step layer STPL1 may be determined (e.g., may be set) in consideration of a wavelength of the second light and a distance from the light emitting stack IL of the second sub-pixel SP2 to the corresponding fourth reflective electrode RL4, so that the second light emitted from the light emitting stack IL of the second sub-pixel SP2 may be reflected. A thickness of the second step layer STPL2 may be determined (e.g., may be set) in consideration of a wavelength of the third light and a distance from the light emitting stack IL of the third sub-pixel SP3 to the corresponding fourth reflective electrode RL4, so that the third light emitted from the light emitting stack IL of the third sub-pixel SP3 may be reflected.

The first step layer STPL1 and the second step layer STPL2 may be formed as a silicon carbonitride (SiCN)-based inorganic film or a silicon oxide (SiOₓ)-based inorganic film, but the present disclosure is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1. In the third sub-pixel SP3, the third reflective electrode RL3 may be disposed on the second step layer STPL2. Each of the third reflective electrodes RL3 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. For example, each of the third reflective electrodes RL3 may include titanium nitride (TiN).

At least one of the first reflective electrodes RL1, the second reflective electrodes RL2, and the third reflective electrodes RL3 may be omitted as needed or desired.

Each of the fourth reflective electrodes RL4 may be disposed on the corresponding third reflective electrode RL3. The fourth reflective electrodes RL4 may be layers for reflecting light from the corresponding light emitting stack IL. The fourth reflective electrodes RL4 may include a metal having a high reflectivity to reflect the light. In addition, because the fourth reflective electrodes RL4 may be electrodes for reflecting or substantially reflecting light from the light emitting elements LE, a thickness of the fourth reflective electrode RL4 may be greater than a thickness of the first reflective electrode RL1, a thickness of the second reflective electrode RL2, and a thickness of the third reflective electrode RL3. Each of the fourth reflective electrodes RL4 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. For example, each of the fourth reflective electrodes RL4 may include aluminum (Al) or titanium (Ti).

A tenth insulating film INS10 may be disposed on the ninth insulating film INS9 and the fourth reflective electrodes RL4. The tenth insulating film INS10 may be an optical auxiliary layer through which light reflected by the reflective electrode layer RL pass therethrough from among the light emitted from the light emitting elements. The tenth insulating film INS10 may be formed as a silicon oxide (SiOₓ)-based inorganic film, but the present disclosure is not limited thereto.

Each of the tenth vias VA10 may penetrate through the tenth insulating film INS10 to be connected to the corresponding exposed fourth reflective electrode RL4. Each of the tenth vias VA10 may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof.

Thicknesses of the tenth vias VA10 in the first sub-pixel SP1, the second sub-pixel SP2, and the third sub-pixel SP3 may be different from each other in order to adjust a resonance distance of the light emitted from the light emitting elements LE. For example, a thickness of the tenth via VA10 in the third sub-pixel SP3 may be smaller than a thickness of the tenth via VA10 in each of the first sub-pixel SP1 and the second sub-pixel SP2. In addition, the thickness of the tenth via VA10 in the second sub-pixel SP2 may be smaller than the thickness of the tenth via VA10 in the first sub-pixel SP1. In other words, distances between the light emitting stack IL and the reflective electrode layer RL in the first sub-pixel SP1, the second sub-pixel SP2, and the third sub-pixel SP3 may be different from each other.

As described above, the presence or the absence of the first and second step layers STPL1 and STPL2 in the first sub-pixel SP1, the second sub-pixel SP2, and the third sub-pixel SP3, and the thickness of each of the first and second step layers STPL1 and STPL2, may be variously determined (e.g., may be variously set) in order to adjust a distance between the light emitting stack IL and the reflective electrode layer RL according to the main wavelengths of the light emitted from the first sub-pixel SP1, the second sub-pixel SP2, and the third sub-pixel SP3.

The first electrode AND of each of the light emitting elements LE may be disposed on the tenth insulating film INS10, and may be connected to the corresponding tenth via VA10. The first electrode AND of each of the light emitting elements LE may be connected to the corresponding drain region DA or the corresponding source region SA of the corresponding pixel transistor PTR through the corresponding tenth via VA10, the corresponding first to fourth reflective electrodes RL1 to RL4, the corresponding first to ninth vias VA1 to VA9, the corresponding first to eighth conductive layers ML1 to ML8, and the corresponding contact terminal CTE. The first electrode AND of each of the light emitting elements LE may include (e.g., may be made of) any one of copper (Cu), aluminum (Al), tungsten (W), molybdenum (Mo), chromium (Cr), gold (Au), titanium (Ti), nickel (Ni), neodymium (Nd), and suitable alloys thereof. For example, the first electrode AND of each of the light emitting elements LE may include (e.g., may be made of) titanium nitride (TiN).

The pixel defining film PDL may be disposed on a partial area of the first electrode AND of each of the light emitting elements LE. The pixel defining film PDL may cover an edge of the first electrode AND of each of the light emitting elements LE. The pixel defining film PDL serves to partition the first emission areas EA1, the second emission areas EA2, and the third emission areas EA3 from each other.

The first emission area EA1 may be defined as an area where the first electrode AND, the light emitting stack IL, and the second electrode CAT are sequentially stacked in the first sub-pixel SP1 to emit light. The second emission area EA2 may be defined as an area where the first electrode AND, the light emitting stack IL, and the second electrode CAT are sequentially stacked in the second sub-pixel SP2 to emit light. The third emission area EA3 may be defined as an area where the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on side surfaces of the first electrode AND of each of the light emitting elements LE. The second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed as silicon oxide (SiOₓ)-based inorganic films, but the present disclosure is not limited thereto. Each of a thickness of the first pixel defining film PDL1, a thickness of the second pixel defining film PDL2, and a thickness of the third pixel defining film PDL3 may be approximately 500 Å.

When the first pixel defining film PDL1, the second pixel defining film PDL2, and the third pixel defining film PDL3 are formed as one pixel defining film PDL, a height of the one pixel defining film PDL may be increased, such that a first encapsulation inorganic film TFE1 may be disconnected due to a step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, in order to prevent or substantially prevent the first encapsulation inorganic film TFE1 from being disconnected due to the step coverage, the first pixel defining film PDL1, the second pixel defining film PDL2, and the third pixel defining film PDL3 may have a cross-sectional structure including a step having a staircase shape. For example, a width of the first pixel defining film PDL1 may be smaller than a width of the second pixel defining film PDL2 and a width of the third pixel defining film PDL3, and the width of the second pixel defining film PDL2 may be greater than the width of the third pixel defining film PDL3. The width of the first pixel defining film PDL1 refers to a length of the first pixel defining film PDL1 in a horizontal direction defined by the first direction DR1 and the second direction DR2.

Each of the plurality of trenches TRC may penetrate through the first pixel defining film PDL1, the second pixel defining film PDL2, and the third pixel defining film PDL3. In addition, in each of the plurality of trenches TRC, the tenth insulating film INS10 may have a shape in which a portion thereof is trenched.

At least one trench TRC may be disposed between the sub-pixels SP1, SP2, and SP3 neighboring (e.g., adjacent to) each other. In FIG. 7, two trenches TRC are illustrated as being disposed between the sub-pixels SP1, SP2, and SP3 neighboring each other, but the present disclosure is not limited thereto.

The light emitting stack IL may include a plurality of intermediate layers. In FIG. 7, the light emitting stack IL is illustrated as having a three-tandem structure including a first stack layer IL1, a second stack layer IL2, and a third stack layer IL3, but the present disclosure is not limited thereto. For example, the light emitting stack IL may have a two-tandem structure including two intermediate layers.

In the three-tandem structure, the light emitting stack IL may have a tandem structure including a plurality of stack layers IL1, IL2, and IL3 for emitting different colored light from each other. For example, the light emitting stack IL may include the first stack layer IL1 for emitting a first light, the second stack layer IL2 for emitting a third light, and the third stack layer IL3 for emitting a second light. The first stack layer IL1, the second stack layer IL2, and the third stack layer IL3 may be sequentially stacked.

The first stack layer IL1 may have a structure in which a first hole transporting layer, a first organic light emitting layer for emitting the first light, and a first electron transporting layer are sequentially stacked. The second stack layer IL2 may have a structure in which a second hole transporting layer, a second organic light emitting layer for emitting the third light, and a second electron transporting layer are sequentially stacked. The third stack layer IL3 may have a structure in which a third hole transporting layer, a third organic light emitting layer for emitting the second light, and a third electron transporting layer are sequentially stacked.

A first charge generation layer may be disposed between the first stack layer IL1 and the second stack layer IL2 to supply holes to the second stack layer IL2 and to supply electrons to the first stack layer IL1. The first charge generation layer may include an N-type charge generation layer for supplying electrons to the first stack layer IL1, and a P-type charge generation layer for supplying holes to the second stack layer IL2. The N-type charge generation layer may include a suitable dopant of a metal material.

A second charge generation layer may be disposed between the second stack layer IL2 and the third stack layer IL3 to supply holes to the third stack layer IL3 and to supply electrons to the second stack layer IL2. The second charge generation layer may include an N-type charge generation layer for supplying electrons to the second stack layer IL2, and a P-type charge generation layer for supplying holes to the third stack layer IL3.

The first stack layer IL1 may be disposed on the first electrodes AND and the pixel defining film PDL. A residual stack layer RIL including (e.g., made of) the same material as that of the first stack layer IL1 may be disposed on a bottom surface of each of the trenches TRC. Due to the trenches TRC, the first stack layer IL1 may be disconnected between the sub-pixels SP1, SP2, and SP3 neighboring (e.g., adjacent to) each other. The second stack layer IL2 may be disposed on the first stack layer IL1. Due to the trenches TRC, the second stack layer IL2 may be disconnected between the sub-pixels SP1, SP2, and SP3 neighboring each other. A cavity ESS or an empty space may be disposed between the residual stack layer RIL and the second stack layer IL2 in each of the trenches TRC. The third stack layer IL3 may be disposed on the second stack layer IL2. The third stack layer IL3 may not be disconnected by the trenches TRC, and may be disposed to cover the second stack layer IL2 in each of the trenches TRC. In other words, in the three-tandem structure, each of the plurality of trenches TRC may be a structure for disconnecting the first and second stack layers IL1 and IL2, the first charge generation layer, and the second charge generation layer of the display element layer EML between the sub-pixels SP1, SP2, and SP3 neighboring (e.g., adjacent to) each other. In addition, in the two-tandem structure, each of the plurality of trenches TRC may be a structure for disconnecting a lower intermediate layer, and a charge generation layer disposed between the lower intermediate layer and an upper intermediate layer.

In order to stably disconnect the first and second stack layers IL1 and IL2 of the display element layer EML between the sub-pixels SP1, SP2, and SP3 neighboring each other, a height of each of the plurality of trenches TRC may be greater than a height of the pixel defining film PDL. The height of each of the plurality of trenches TRC refers to a length of each of the plurality of trenches TRC in the third direction DR3. The height of the pixel defining film PDL refers to a length of the pixel defining film PDL in the third direction DR3. In order to disconnect the first and second stack layers IL1 and IL2 of the display element layer EML between the sub-pixels SP1, SP2, and SP3 neighboring each other, other suitable structures may exist instead of the trenches TRC. For example, instead of the trenches TRC, partition walls having a reverse tapered shape may be disposed on the pixel defining film PDL.

The number of stack layers IL1, IL2, and IL3 for emitting different colored light from each other is not limited to that illustrated in FIG. 7. For example, the light emitting stack IL may include two intermediate layers. In this case, any one of the two intermediate layers may be the same or substantially the same as the first stack layer IL1, and the other of the two intermediate layers may include a second hole transporting layer, a second organic light emitting layer, a third organic light emitting layer, and a second electron transporting layer. In this case, a charge generation layer for supplying electrons to any one intermediate layer and for supplying holes to the other intermediate layer may be disposed between the two intermediate layers.

In addition, FIG. 7 illustrates that the first to third stack layers IL1, IL2, and IL3 are all disposed in the first emission area EA1, the second emission area EA2, and the third emission area EA3, but the present disclosure is not limited thereto. For example, the first stack layer IL1 may be disposed in the first emission area EA1, and may not be disposed in the second emission area EA2 and the third emission area EA3. In addition, the second stack layer IL2 may be disposed in the second emission area EA2, and may not be disposed in the first emission area EA1 and the third emission area EA3. In addition, the third stack layer IL3 may be disposed in the third emission area EA3, and may not be disposed in the first emission area EA1 and the second emission area EA2. In this case, first to third color filters CF1, CF2, and CF3 of the optical layer OPL may be omitted as needed or desired.

The second electrode CAT may be disposed on the third stack layer IL3. The second electrode CAT may be disposed on the third stack layer IL3 in each of the plurality of trenches TRC. The second electrode CAT may include (e.g., may be made of) a transparent conductive material (TCO), such as indium tin oxide (ITO) or indium zinc oxide (IZO), which is capable of transmitting light therethrough, or a semi-transmissive conductive material, such as magnesium (Mg), silver (Ag), or an alloy of magnesium (Mg) and silver (Ag). When the second electrode CAT includes (e.g., is made of) the semi-transmissive conductive material, a light emission efficiency of each of the first to third sub-pixels SP1, SP2, and SP3 may be increased by a micro cavity.

The encapsulation layer TFE may be disposed on the display element layer EML. The encapsulation layer TFE may include at least one inorganic film TFE1 or TFE2 in order to prevent or substantially prevent oxygen and/or moisture from permeating into the display element layer EML. For example, the encapsulation layer TFE may include a first encapsulation inorganic film TFE1 and a second encapsulation inorganic film TFE2.

The first encapsulation inorganic film TFE1 may be disposed on the second electrode CAT. The first encapsulation inorganic film TFE1 may be formed as multiple films in which one or more inorganic films of a silicon nitride (SiNₓ) film, a silicon oxynitride (SiON) film, and a silicon oxide (SiOₓ) film are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed as a titanium oxide (TiOₓ) film or an aluminum oxide (AIOₓ) film, but the present disclosure is not limited thereto. The second encapsulation inorganic film TFE2 may be formed by an atomic layer deposition (ALD) process. A thickness of the second encapsulation inorganic film TFE2 may be smaller than a thickness of the first encapsulation inorganic film TFE1.

An organic film APL may be disposed on the encapsulation layer TFE, and may be a layer for increasing an interfacial adhesive strength between the encapsulation layer TFE and the optical layer OPL. The organic film APL may include (e.g., may be made of) an acrylic resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be disposed on the organic film APL.

The first color filter CF1 may overlap with the first emission area EA1 of the first sub-pixel SP1. The first color filter CF1 may transmit the first light therethrough, or in other words, light of a blue wavelength band. Therefore, the first color filter CF1 may transmit the first light from among the light emitted from the first emission area EA1 therethrough.

The second color filter CF2 may overlap with the second emission area EA2 of the second sub-pixel SP2. The second color filter CF2 may transmit the second light therethrough, or in other words, light of a green wavelength band. Therefore, the second color filter CF2 may transmit the second light from among the light emitted from the second emission area EA2 therethrough.

The third color filter CF3 may overlap with the third emission area EA3 of the third sub-pixel SP3. The third color filter CF3 may transmit the third light therethrough, or in other words, light of a red wavelength band. Therefore, the third color filter CF3 may transmit the third light from among the light emitted from the third emission area EA3 therethrough.

The plurality of lenses LNS may be disposed on the first color filter CF1, the second color filter CF2, and the third color filter CF3, respectively. Each of the plurality of lenses LNS may be a structure for increasing a ratio of light directed to a front surface of the display device 10. While FIG. 7 illustrates that each of the plurality of lenses LNS have a cross-sectional shape of a convex in an upward direction, the present disclosure is not limited thereto.

The filling layer FIL may be disposed on the plurality of lenses LNS. The filling layer FIL may have a suitable refractive index (e.g., a predetermined refractive index) so that light travels in the third direction DR3 at an interface between the plurality of lenses LNS and the filling layer FIL. In addition, the filling layer FIL may be a planarizing layer. The filling layer FIL may be an organic film including (e.g., made of) an acrylic resin, an epoxy resin, a phenolic resin, a polyamide resin, a polyimide resin, or the like.

The cover layer CVL may be disposed on the filling layer FIL. The cover layer CVL may be a glass substrate or a resin such as a polymer resin. When the cover layer CVL is a glass substrate, the cover layer CVL may be attached onto the filling layer FIL. In this case, the filling layer FIL may serve to adhere to the cover layer CVL. When the cover layer CVL is a glass substrate, the cover layer CVL may serve as an encapsulation substrate. When the cover layer CVL is a resin, such as a polymer resin, the cover layer CVL may be directly applied onto the filling layer FIL.

The polarizing plate POL may be disposed on one surface of the cover layer CVL. The polarizing plate POL may be a structure for preventing or substantially preventing a deterioration in visibility due to external light reflection. The polarizing plate POL may include a linear polarizing plate and a phase retardation film. For example, the phase retardation film may include (e.g., may be) a λ/4 plate (e.g., a quarter-wave plate), but the present disclosure is not limited thereto. However, when visibility due to external light reflection is sufficiently improved by the first to third color filters CF1, CF2, and CF3, the polarizing plate POL may be omitted as needed or desired.

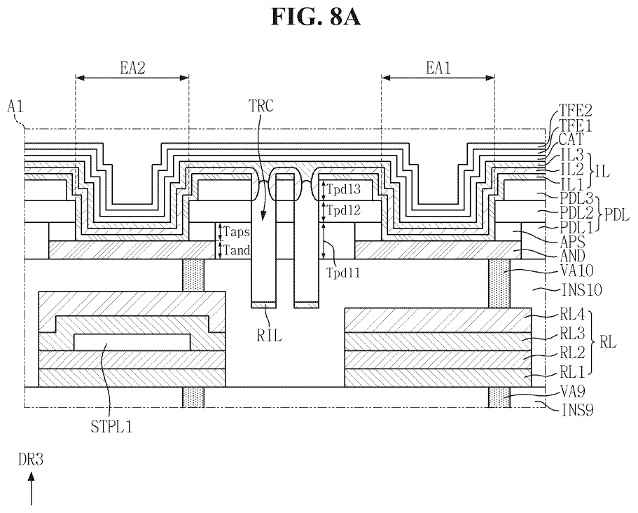

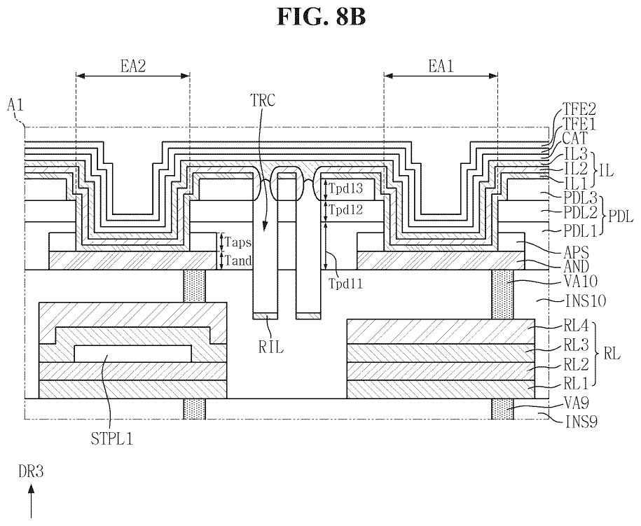

FIG. 8A is a cross-sectional view illustrating an example of the area A1 of FIG. 7 in more detail. Hereinafter, a residual film APS will be described in more detail with reference to FIG. 8A.

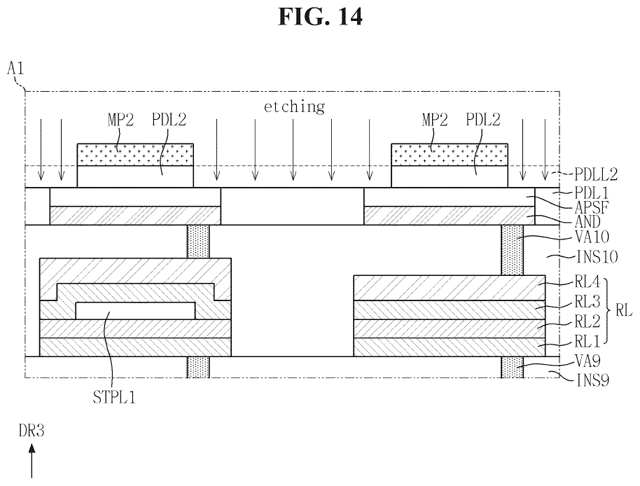

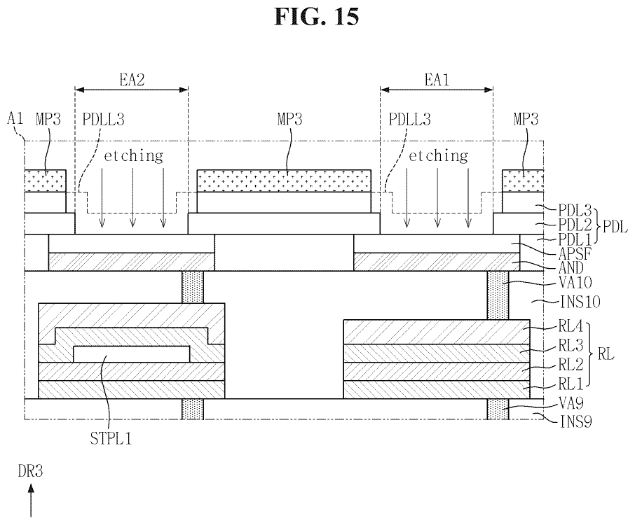

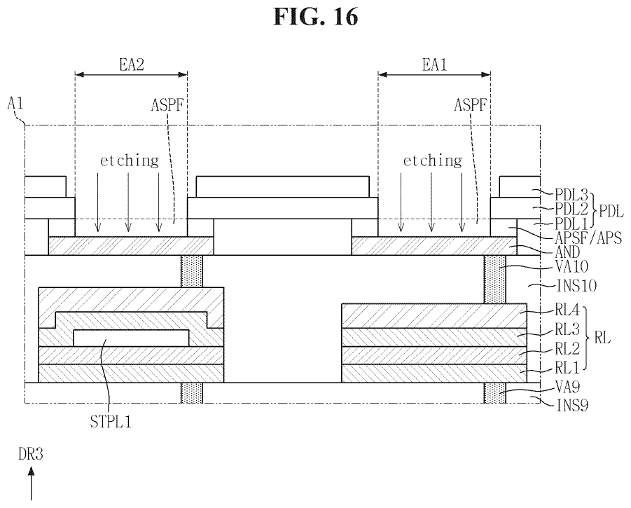

Referring to FIG. 8A, the residual film APS may be a residue remaining after a protective film APSF (e.g., see FIGS. 15 and 16) is removed. In more detail, as illustrated in FIGS. 14 and 15, when the first electrode AND includes (e.g., is made of) titanium nitride (TiN), in an ashing process of removing a second mask pattern MP2 (e.g., see FIG. 14) and a third mask pattern (e.g., see FIG. 15) formed in order to pattern a second pixel defining film PDL2 and a third pixel defining film PDL3, the protective film APSF may be a film for preventing or substantially preventing an upper surface of the first electrode AND from being oxidized by oxygen (O₂). In addition, the protective film APSF (e.g., see FIGS. 14 and 15) may be a film for preventing or substantially preventing the first electrode AND from being etched together with the second pixel defining film PDL2 and the third pixel defining film PDL3 in a process of etching the second pixel defining film PDL2 and the third pixel defining film PDL3 in order to form the emission areas EA1, EA2, and EA3. After the emission areas EA1, EA2, and EA3 are formed by etching the second pixel defining film PDL2 and the third pixel defining film PDL3, the protective film APSF (e.g., see FIG. 16) that is not covered by the second pixel defining film PDL2 may be removed.

The residual film APS may be disposed on an edge of the upper surface of the first electrode AND. The residual film APS may be disposed between the first electrode AND and the second pixel defining film PDL2 in the third direction DR3. A thickness Taps of the residual film APS may be smaller than a thickness Tand of the first electrode AND.

An upper surface of the residual film APS and an upper surface of the first pixel defining film PDL1 may be connected to each other so as to be flat or substantially flat. Therefore, the sum of the thickness Taps of the residual film APS and the thickness Tand of the first electrode AND may be the same or substantially the same as a thickness Tpdl1 of the first pixel defining film PDL1. In addition, the thickness Tpdl1 of the first pixel defining film PDL1 may be greater than a thickness Tpdl2 of the second pixel defining film PDL2. Further, the thickness Tpdl1 of the first pixel defining film PDL1 may be greater than a thickness Tpdl3 of the third pixel defining film PDL3.

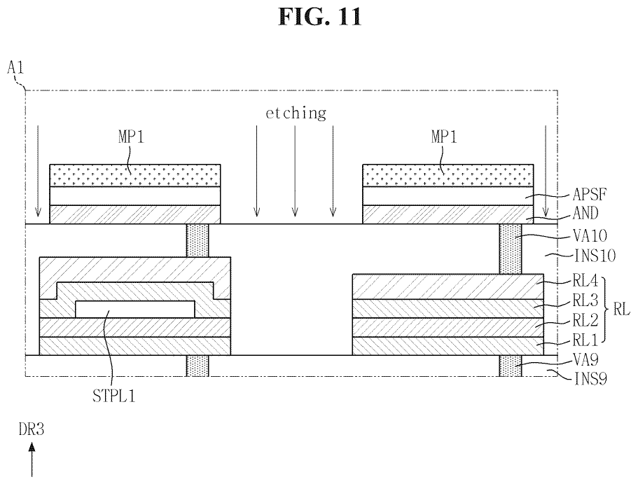

As illustrated in FIG. 11, the protective film APSF and the first electrode AND may be patterned (e.g., etching) together, and thus, a first side surface of the residual film APS and one side surface of the first electrode AND may be connected to each other so as to be flat or substantially flat. In other words, the first side surface of the residual film APS and the one side surface of the first electrode AND may be aligned with each other (e.g., may be co-planar with each other) in the third direction DR3.

As illustrated in FIGS. 15 and 16, the protective film APSF (e.g., see FIG. 15) is removed using the second pixel defining film PDL2 as a mask (e.g., see FIG. 16), and thus, a second side surface of the residual film APS and one side surface of the second pixel defining film PDL2 may be connected to each other so as to be flat or substantially flat. In other words, the second side surface of the residual film APS and the one side surface of the second pixel defining film PDL2 may be aligned with each other in the third direction DR3. The second side surface of the residual film APS may be an inner side surface of the residual film APS disposed closer to the center of the first electrode AND, and the first side surface of the residual film APS may be an outer side surface of the residual film APS disposed closer to the edge of the first electrode AND.

The light emitting stack IL may be disposed on the upper surface of the first electrode AND, the second side surface of the residual film APS, a portion of an upper surface and the one side surface of the second pixel defining film PDL2, and an upper surface and a side surface of the third pixel defining film PDL3.

The residual film APS may include a different material from those of the first pixel defining film PDL1, the second pixel defining film PDL2, and the third pixel defining film PDL3. For example, the residual film APS may be formed as an inorganic film such as a silicon nitride (SiNₓ) film, and the first pixel defining film PDL1, the second pixel defining film PDL2, and the third pixel defining film PDL3 may be formed as inorganic films such as silicon oxide (SiOₓ) films, but the present disclosure is not limited thereto.

A width of the second pixel defining film PDL2 disposed between the emission areas EA1, EA2, and EA3 that are adjacent to each other may be greater than a width of the first pixel defining film PDL1 disposed between the emission areas EA1, EA2, and EA3 that are adjacent to each other. In addition, the width of the second pixel defining film PDL2 disposed between the emission areas EA1, EA2, and EA3 that are adjacent to each other may be greater than a width of the third pixel defining film PDL3 disposed between the emission areas EA1, EA2, and EA3 that are adjacent to each other.

While the width of the first pixel defining film PDL1 disposed between the emission areas EA1, EA2, and EA3 that are adjacent to each other is illustrated as being smaller than the width of the third pixel defining film PDL3 disposed between the emission areas EA1, EA2, and EA3 that are adjacent to each other, the present disclosure is not limited thereto. In some embodiments, the width of the first pixel defining film PDL1 disposed between the emission areas EA1, EA2, and EA3 that are adjacent to each other may be greater than the width of the third pixel defining film PDL3 disposed between the emission areas EA1, EA2, and EA3 that are adjacent to each other.

FIG. 8B is a cross-sectional view illustrating another example of the area A1 of FIG. 7 in more detail.

The embodiments described in more detail hereinafter with reference to FIG. 8B may be different from those described above with reference to FIG. 8A, in that in FIG. 8B, the first pixel defining film PDL1 may be disposed on the residual film APS. As such, the differences therebetween may be mainly described in more detail hereinafter, and redundant description may not be repeated.

Referring to FIG. 8B, the first pixel defining film PDL1 may be disposed to cover the upper surface of the residual film APS. The first pixel defining film PDL1 may be disposed between the residual film APS and the second pixel defining film PDL2 in the third direction DR3. The thickness Tpdl1 of the first pixel defining film PDL1 may be greater than the sum of the thickness Taps of the residual film APS and the thickness Tand of the first electrode AND.

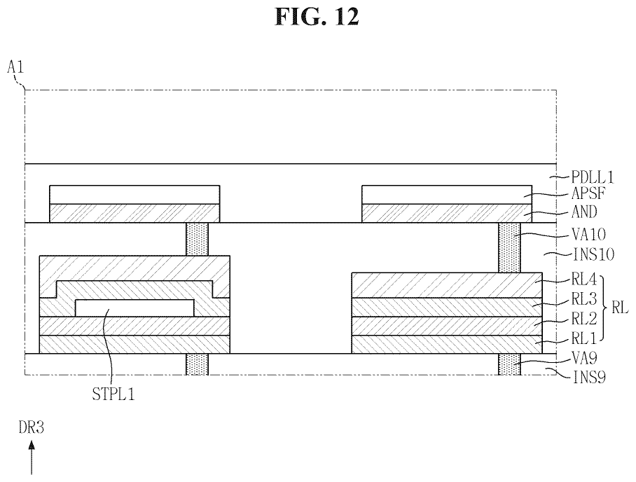

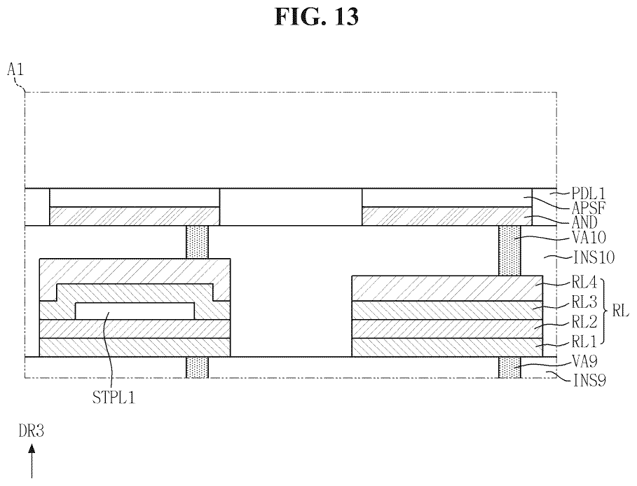

When the first pixel defining film PDL1 is disposed on the upper surface of the residual film APS, a process of removing a portion of a first pixel defining layer PDLL1 (e.g., see FIG. 12) through a polishing process (e.g., see FIG. 13) may be omitted, and thus, a process efficiency may be increased.

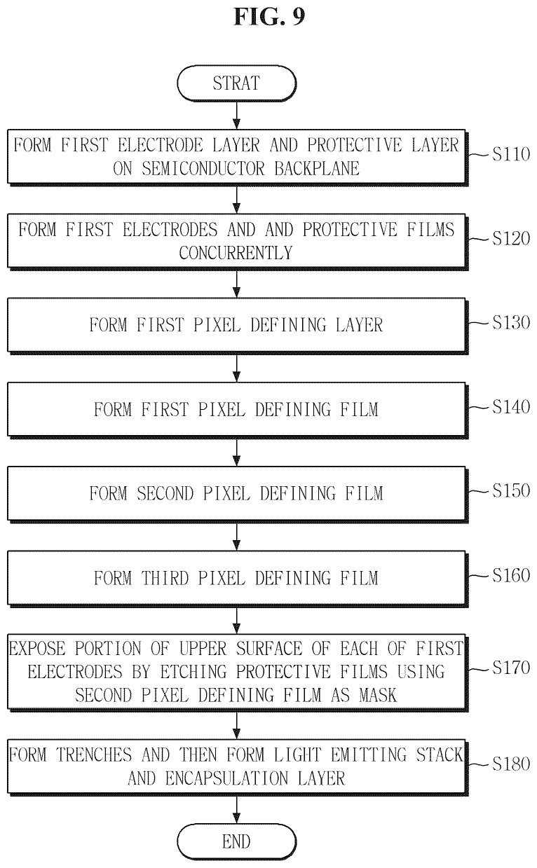

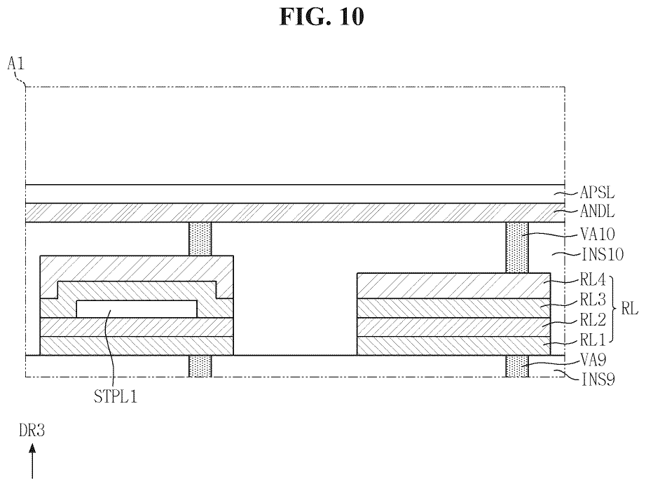

FIG. 9 is a flowchart illustrating a method for manufacturing a display panel according to an embodiment. FIGS. 10 through 17 are cross-sectional views illustrating a method for manufacturing a display panel according to an embodiment corresponding to the area A1 in FIG. 7 in more detail.

Hereinafter, a method for manufacturing a display panel according to an embodiment will be described in more detail with reference to FIGS. 7, 9, and 10 to 17.

Referring to FIG. 9, as illustrated in FIGS. 7 and 10, a first electrode layer ANDL and a protective layer APSL may be formed on the semiconductor backplane SBP (S110). In other words, the first electrode layer ANDL and the protective layer APSL may be formed on the semiconductor substrate SSUB of the semiconductor backplane SBP.

The light emitting element backplane EBP may be formed on the semiconductor backplane SBP, and the first electrode layer ANDL and the protective layer APSL may be formed on the light emitting element backplane EBP.

The first to eighth conductive layers ML1 to ML8, the first to ninth vias VA1 to VA9, and the first to ninth insulating films INS1 to INS9 of the light emitting element backplane EBP may be formed on the semiconductor substrate SSUB.

In more detail, the first insulating film INS1 is formed on the semiconductor substrate SSUB. The first vias VA1 penetrating through the first insulating film INS1 to be connected to the contact terminals CTE of the semiconductor substrate SSUB, respectively, may be formed through a photolithography process. The first conductive layers ML1 connected to the first vias VA1, respectively, may be formed on the first insulating film INS1 through a photolithography process. Then, the second insulating film INS2 may be formed on the first conductive layers ML1, and the second vias VA2 penetrating through the second insulating film INS2 to be connected to the first conductive layers ML1, respectively, may be formed through a photolithography process. The second conductive layers ML2 connected to the second vias VA2, respectively, may be formed on the second insulating film INS2 through a photolithography process. Then, the third insulating film INS3 may be formed on the second conductive layers ML2, and the third vias VA3 penetrating through the third insulating film INS3 to be connected to the second conductive layers ML2, respectively, may be formed through a photolithography process. The third conductive layers ML3 connected to the third vias VA3, respectively, may be formed on the third insulating film INS3 through a photolithography process. Then, the fourth insulating film INS4 may be formed on the third conductive layers ML3, and the fourth vias VA4 penetrating through the fourth insulating film INS4 to be connected to the third conductive layers ML3, respectively, may be formed through a photolithography process. The fourth conductive layers ML4 connected to the fourth vias VA4, respectively, may be formed on the fourth insulating film INS4 through a photolithography process.

Then, the fifth insulating film INS5 may be formed on the fourth conductive layers ML4, and the fifth vias VA5 penetrating through the fifth insulating film INS5 to be connected to the fourth conductive layers ML4, respectively, may be formed through a photolithography process. The fifth conductive layers ML5 connected to the fifth vias VA5, respectively, may be formed on the fifth insulating film INS5 through a photolithography process. Then, the sixth insulating film INS6 may be formed on the fifth conductive layers ML5, and the sixth vias VA6 penetrating through the sixth insulating film INS6 to be connected to the fifth conductive layers ML5, respectively, may be formed through a photolithography process. The sixth conductive layers ML6 connected to the sixth vias VA6, respectively, may be formed on the sixth insulating film INS6 through a photolithography process. Then, the seventh insulating film INS7 may be formed on the sixth conductive layers ML6, and the seventh vias VA7 penetrating through the seventh insulating film INS7 to be connected to the sixth conductive layers ML6, respectively, may be formed through a photolithography process. The seventh conductive layers ML7 connected to the seventh vias VA7, respectively, may be formed on the seventh insulating film INS7 through a photolithography process, and then, the eighth insulating film INS8 may be formed on the seventh conductive layers ML7. The eighth vias VA8 penetrating through the eighth insulating film INS8 to be connected to the seventh conductive layers ML7, respectively, may be formed through a photolithography process, and the eighth conductive layers ML8 connected to the eighth vias VA8, respectively, may be formed on the eighth insulating film INS8 through a photolithography process. Then, the ninth insulating film INS9 may be formed on the eighth conductive layers ML8, and the ninth vias VA9 penetrating through the ninth insulating film INS9 to be connected to the eighth conductive layers ML8, respectively, may be formed in the ninth insulating film INS9 through a photolithography process.

Then, the first reflective electrodes RL1 of the reflective electrode layer RL connected to the ninth vias VA9, respectively, may be formed on the ninth insulating film INS9. The second reflective electrodes RL2 of the reflective electrode layer RL may be formed on the first reflective electrodes RL1, respectively. Then, the first step layers STPL1 may be formed on the second reflective electrodes RL2 of the reflective electrode layer RL in the second sub-pixel SP2 and the third sub-pixel SP3, respectively, and the second step layer STPL2 may be formed on the first step layer STPL1 in the third sub-pixel SP3. Then, the third reflective electrodes RL3 of the reflective electrode layer RL may be formed on the second reflective electrode RL2 of the reflective electrode layer RL in the first sub-pixel SP1, on the first step layer STPL1 in the second sub-pixel SP2, and on the second step layer STPL2 in the third sub-pixel SP3, respectively. The fourth reflective electrodes RL4 of the reflective electrode layer RL may be formed on the third reflective electrodes RL3 of the reflective electrode layer RL, respectively.

Then, the tenth insulating film INS10 covering the reflective electrode layer RL may be formed, and the tenth vias VA10 penetrating through the tenth insulating film INS10 to be connected to the fourth reflective electrodes RL4, respectively, may be formed. In addition, the first electrode layer ANDL connected to each of the tenth vias VA10 may be formed on the tenth insulating film INS10, and the protective layer APSL may be formed on the first electrode layer ANDL. The first electrode layer ANDL may include (e.g., may be made of) titanium nitride (TiN), and the protective layer APSL may include (e.g., may be made of) silicon nitride (SiNₓ), but the present disclosure is not limited thereto.

As illustrated in FIG. 11, the first electrodes AND and the protective films APSF may be formed concurrently or all at once (S120).

The first electrodes AND and the protective films APSF may be formed concurrently with each other (e.g., all at once) by forming first mask patterns MP1 on the protective layer APSL (e.g., see FIG. 10), and etching the first electrode layer ANDL and the protective layer APSL using the first mask patterns MP1 as masks. The first mask patterns MP1 are formed on the protective layer APSL in areas where the first electrodes AND are to be formed. The first mask patterns MP1 may be photoresist patterns. The first electrode layer ANDL1 and the protective layer APSL that is exposed without being covered by the first mask patterns MP1 may be etched at once through dry etching. As such, the first electrodes AND and the protective films APSF that are protected without being etched by the first mask patterns MP1 may be formed.

The protective film APSF and the first electrode AND are patterned together, and thus, a first side surface of the protective film APSF and one side surface of the first electrode AND may be connected to each other so as to be flat or substantially flat. In other words, the first side surface of the protective film APSF and the one side surface of the first electrode AND may be aligned with each other in the third direction DR3.

As illustrated in FIG. 12, a first pixel defining layer PDLL1 may be formed (S130).

The first mask patterns MP1 may be removed, and the first pixel defining layer PDLL1 covering the first electrodes AND and the protective films APSF may be formed. The first pixel defining layer PDLL1 may be disposed on an upper surface and side surfaces of each of the protective films APSF, and on an upper surface and side surfaces of each of the first electrodes AND.

As illustrated in FIG. 13, the first pixel defining film PDL1 may be formed (S140).

The first pixel defining film PDL1 disposed between the first electrodes AND and between the protective films APSF may be formed through a polishing process. The first pixel defining layer PDLL1 disposed on the upper surfaces of the protective films APSF may be removed through the polishing process. As such, the first pixel defining film PDL1 disposed between the first electrodes AND that are adjacent to each other and between the protective films APSF that are adjacent to each other may be formed. In addition, the upper surface of the protective film APSF and an upper surface of the first pixel defining film PDL1 may be connected to each other so as to be flat or substantially flat. The first pixel defining film PDL1 may be disposed on the side surfaces of each of the protective films APSF and on the side surfaces of each of the first electrodes AND. The polishing process may be a chemical mechanical polishing (CMP) process.

As illustrated in FIG. 14, the second pixel defining film PDL2 may be formed (S150).

A second pixel defining layer PDLL2 may be formed on the protective films APSF and the first pixel defining film PDL1. The second pixel defining layer PDLL2 may be disposed to cover the protective films APSF and the first pixel defining film PDL1. A thickness of the second pixel defining layer PDLL2 may be smaller than a thickness of the first pixel defining film PDL1. The second pixel defining layer PDLL2 may include (e.g., may be made of) silicon oxide, but the present disclosure is not limited thereto.

In addition, second mask patterns MP2 may be formed on the second pixel defining layer PDLL2. Then, the second pixel defining film PDL2 may be formed by etching the second pixel defining layer PDLL2 using the second mask patterns MP2 as masks. The protective films APSF may be exposed due to the etching of the second pixel defining layer PDLL2 that is not covered by the second mask patterns MP2.

In a process of etching the second pixel defining layer PDLL2 in order to form the second pixel defining film PDL2, it may be possible to prevent or substantially prevent the first electrodes AND from being etched due to the protective films APSF disposed on the upper surfaces of the first electrodes AND. In addition, after the second pixel defining film PDL2 is formed, the second mask patterns MP2 may be removed. In this case, the protective film APSF may be disposed on the upper surface of each of the first electrodes AND, and thus, it may be possible to prevent or substantially prevent the upper surface of each of the first electrodes AND from being oxidized by oxygen (O₂) in an ashing process of removing the second mask patterns MP2.

As illustrated in FIG. 15, the third pixel defining film PDL3 may be formed (S160).

A third pixel defining layer PDLL3 may be formed on the protective films APSF and the second pixel defining film PDL2. The third pixel defining layer PDLL3 may be disposed to cover the protective films APSF and the second pixel defining film PDL2. A thickness of the third pixel defining layer PDLL3 may be smaller than the thickness of the first pixel defining film PDL1. The third pixel defining layer PDLL3 may include (e.g., may be made of) silicon oxide, but the present disclosure is not limited thereto.

In addition, third mask patterns MP3 may be formed on the third pixel defining layer PDLL3. Then, the third pixel defining film PDL3 may be formed by etching the third pixel defining layer PDLL3 using the third mask patterns MP3 as masks. The protective films APSF may be exposed due to the etching of the third pixel defining layer PDLL3 that is not covered by the third mask patterns MP3.

In a process of etching the third pixel defining layer PDLL3 in order to form the third pixel defining film PDL3, it may be possible to prevent or substantially prevent the first electrodes AND from being etched due to the protective films APSF disposed on the upper surfaces of the first electrodes AND. In addition, after the third pixel defining film PDL3 is formed, the third mask patterns MP3 may be removed. In this case, the protective film APSF may be disposed on the upper surface of each of the first electrodes AND, and thus, it may be possible to prevent or substantially prevent the upper surface of each of the first electrodes AND from being oxidized by oxygen (O₂) in an ashing process of removing the third mask patterns MP3.

In addition, a width of the third mask pattern MP3 may be smaller than a width of the second mask pattern MP2. As such, the second pixel defining film PDL2 and the third pixel defining film PDL3 may have a cross-sectional structure including a step having a staircase shape, and the first encapsulation inorganic film TFE1 may be prevented or substantially prevented from being disconnected due to a step coverage.

As illustrated in FIG. 16, a portion of the upper surface of each of the first electrodes AND may be exposed by etching the protective films APSF using the second pixel defining film PDL2 as a mask (S170).

The residual film APS, which may be a residue remaining after etching the protective films APSF, may be disposed on the edge of each of the first electrodes AND. The protective film APSF may be removed using the second pixel defining film PDL2 as the mask, and thus, a second side surface of the residual film APS and one side surface of the second pixel defining film PDL2 may be connected to each other so as to be flat or substantially flat. In other words, the second side surface of the residual film APS and the one side surface of the second pixel defining film PDL2 may be aligned with each other in the third direction DR3. The second side surface of the residual film APS may be an inner side of the residual film APS disposed closer to the center of the first electrode AND.

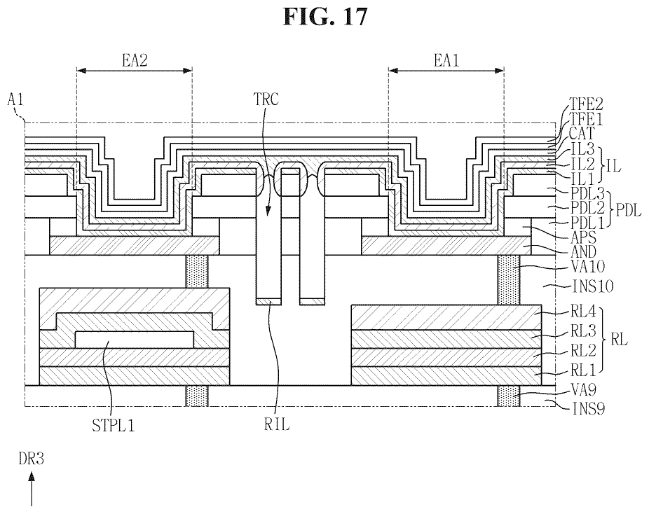

As illustrated in FIG. 17, the trenches TRC may be formed, and then the light emitting stack IL and the encapsulation layer TFE may be formed (S180).

The trenches TRC penetrating through the first pixel defining film PDL1, the second pixel defining film PDL2, the third pixel defining film PDL3, and a portion of the tenth insulating film INS10 may be formed. Then, the first stack layer IL1, the second stack layer IL2, and the third stack layer IL3 of the light emitting stack IL may be formed on the first electrodes AND, the first pixel defining film PDL1, the second pixel defining film PDL2, and the third pixel defining film PDL3. In this case, the first stack layer IL1 and the second stack layer IL2 may be disconnected in each of the trenches TRC. Then, the second electrode CAT of the light emitting elements LE may be formed on the third stack layer IL3.

The first encapsulation inorganic film TFE1 and the second encapsulation inorganic film TFE2 of the encapsulation layer TFE may be sequentially formed on the second electrode CAT. The first encapsulation inorganic film TFE1 may be formed through a chemical vapor deposition (CVD) process, and the second encapsulation inorganic film TFE2 may be formed through an atomic layer deposition (ALD) process.

Then, referring to FIG. 7, the organic film APL may be formed on the encapsulation layer TFE, and the first color filters CF1 overlapping with the first emission areas EA1, the second color filters CF2 overlapping with the second emission areas EA2, and the third color filters CF3 overlapping with the third emission areas EA3 may be formed on the organic film APL.

Then, the plurality of lenses LNS may be formed on the first color filters CF1, the second color filters CF2, and the third color filters CF3, respectively. In other words, the plurality of lenses LNS may be formed to correspond to the color filters CF1, CF2, and CF3 in a one-to-one manner.

The filling layer FIL may be formed on the plurality of lenses LNS, and the cover layer CVL may be provided on the filling layer FIL.

The cover layer CVL may be a glass substrate or a resin, such as a polymer resin. When the cover layer CVL is the glass substrate, the cover layer CVL may serve as an encapsulation substrate, and the filling layer FIL may serve to adhere to the cover layer CVL. When the cover layer CVL is the resin such as the polymer resin, the cover layer CVL may be directly applied onto the filling layer FIL.

Then, the polarizing plate POL may be attached onto the cover layer CVL.

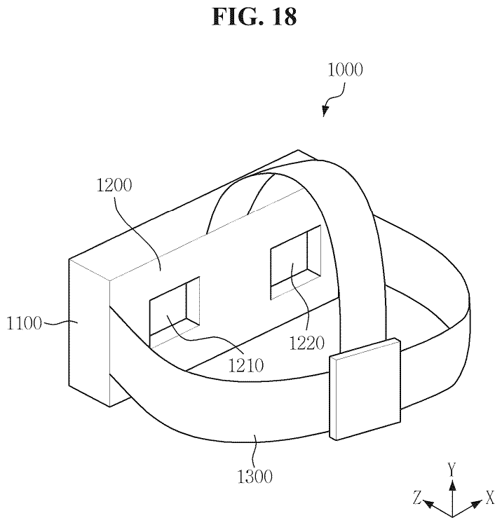

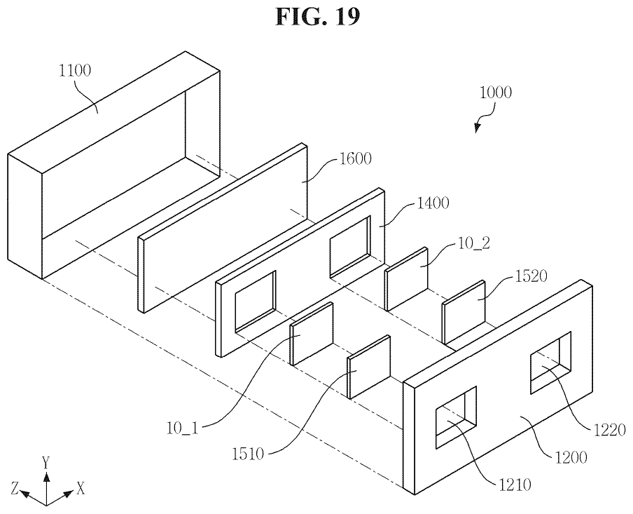

FIG. 18 is a perspective view illustrating a head mounted display according to an embodiment. FIG. 19 is an exploded perspective view illustrating an example of the head mounted display of FIG. 18.

Referring to FIGS. 18 and 19, a head mounted display 1000 according to an embodiment includes a first display device 10_1, a second display device 102, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to a user's left eye, and the second display device 102 provides an image to a user's right eye. Each of the first display device 10_1 and the second display device 10_2 may be the same or substantially the same as the display device 10 described above with reference to FIGS. 1 and 2, and thus, redundant description of the first display device 10_1 and the second display device 10_2 may not be repeated.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600, and may be disposed between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source input from the outside into digital video data DATA, and may transmit the digital video data DATA to the first display device 10_1 and the second display device 10_2 through the connector.

The control circuit board 1600 may transmit digital video data DATA corresponding to a left eye image optimized for the user's left eye to the first display device 10_1, and may transmit digital video data DATA corresponding to a right eye image optimized for the user's right eye to the second display device 10_2. As another example, the control circuit board 1600 may transmit the same digital video data DATA to the first display device 10_1 and the second display device 10_2.

The display device housing 1100 serves to house the first display device 10_1, the second display device 102, the middle frame 1400, the first optical member 1510, the second optical member 1520, and the control circuit board 1600 therein. The housing cover 1200 is disposed to cover one opened surface of the display device housing 1100. The housing cover 1200 may include the first eyepiece 1210 on which the user's left eye is to be disposed, and the second eyepiece 1220 on which the user's right eye is to be disposed. While FIGS. 18 and 19 illustrate that the first eyepiece 1210 and the second eyepiece 1220 are separately disposed, the present disclosure is not limited thereto. The first eyepiece 1210 and the second eyepiece 1220 may be merged together as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

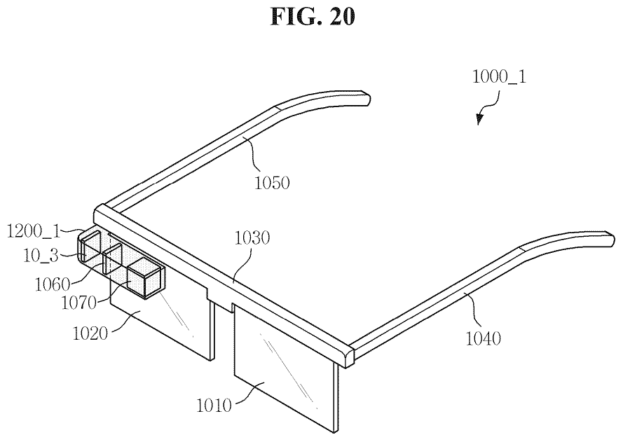

The head mounted band 1300 serves to fix the display device housing 1100 to a user's head, so that the first eyepiece 1210 and the second eyepiece 1220 of the housing cover 1200 may be maintained in a state where they are disposed on the user's left eye and right eye, respectively. When the display device housing 11010 is implemented to have a light weight and a small size, the head mounted display 1000 may include an eyeglass frame as illustrated in FIG. 20, instead of the head mounted band 1300.

In addition, the head mounted display 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 20 is a perspective view illustrating a head mounted display according to another embodiment.

Referring to FIG. 20, a head mounted display 1000_1 according to another embodiment may be a glasses-type display device in which a display device housing 1200_1 is implemented to have a light weight and a small size. The head mounted display 1000_1 according to another embodiment may include a display device 10_3, a left eye lens 1010, a right eye lens 1020, a support frame 1030, glasses frame legs 1040 and 1050, an optical member 1060, an optical path conversion member 1070, and a display device housing 1200_1.

The display device housing 1200_1 may accommodate the display device 10_3, the optical member 1060, and the optical path conversion member 1070. An image displayed on the display device 103 may be magnified by the optical member 1060, converted in an optical path by the optical path conversion member 1070, and provided to a user's right eye through the right eye lens 1020. As such, a user may view an augmented reality image in which a virtual image displayed on the display device 10_3 through his/her right eye and a real image seen through the right eye lens 1020 are combined with each other.

While FIG. 20 illustrates that the display device housing 1200_1 is disposed at a right end of the support frame 1030, the present disclosure is not limited thereto. For example, the display device housing 1200_1 may be disposed at a left end of the support frame 1030, and in this case, an image of the display device 10_3 may be provided to a user's left eye. As another example, the display device housings 1200_1 may be disposed at both the left and right ends of the support frame 1030, and in this case, the user may view an image displayed on the display device 10_3 through both his/her left and right eyes.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
an insulating film on the substrate;
a first electrode on the insulating film;
a residual film on an edge of an upper surface of the first electrode;
a first pixel defining film on a side surface of the first electrode and a first side surface of the residual film;
a second pixel defining film on the residual film and the first pixel defining film;
a trench penetrating through the first pixel defining film and the second pixel defining film;
a light emitting stack on the upper surface of the first electrode and the second pixel defining film; and
a second electrode on the light emitting stack.

2. The display device of claim 1, wherein a sum of a thickness of the first electrode and a thickness of the residual film is the same as a thickness of the first pixel defining film.

3. The display device of claim 1, wherein a thickness of the residual film is smaller than a thickness of the first electrode.

4. The display device of claim 1, wherein an upper surface of the residual film and an upper surface of the first pixel defining film are connected to each other to be flat.

5. The display device of claim 1, wherein the first side surface of the residual film and the side surface of the first electrode are connected to each other to be flat.

6. The display device of claim 1, wherein a second side surface of the residual film opposite to the first side surface of the residual film and one side surface of the second pixel defining film are connected to each other to be flat.

7. The display device of claim 6, wherein the light emitting stack is located on the second side surface of the residual film and the one side surface of the second pixel defining film.

8. The display device of claim 1, wherein the residual film comprises a different material from those of the first pixel defining film and the second pixel defining film.

9. The display device of claim 1, wherein the residual film comprises silicon nitride, and each of the first pixel defining film and the second pixel defining film comprises silicon oxide.

10. The display device of claim 1, wherein a thickness of the first pixel defining film is greater than a thickness of the second pixel defining film.

11. The display device of claim 1, wherein a width of the second pixel defining film located between the first electrode and another first electrode adjacent to the first electrode is greater than a width of the first pixel defining film.

12. The display device of claim 1, further comprising a third pixel defining film on the second pixel defining film.

13. The display device of claim 12, wherein a thickness of the first pixel defining film is greater than a thickness of the third pixel defining film.

14. The display device of claim 12, wherein a width of the third pixel defining film located between the first electrode and another first electrode adjacent to the first electrode is greater than a width of the first pixel defining film.

15. The display device of claim 12, wherein a width of the first pixel defining film located between the first electrode and another first electrode adjacent to the first electrode is greater than a width of the third pixel defining film.

16. The display device of claim 1, wherein the first pixel defining film is located on the residual film.

17. A method for manufacturing a display device, comprising:
sequentially forming a first electrode layer and a protective layer on a substrate;
forming first electrodes and protective films respectively disposed on the first electrodes by forming a first mask pattern on the protective layer, and etching the first electrode layer and the protective layer using the first mask pattern as a mask;
removing the first mask pattern and forming a first pixel defining layer covering the protective films;
forming a first pixel defining film between the first electrodes and the protective layer by removing the first pixel defining layer through a polishing process;
forming a second pixel defining layer on the protective films and the first pixel defining film;
forming a second pixel defining film by forming a second mask pattern on the second pixel defining layer, and etching the second pixel defining layer using the second mask pattern as a mask; and
exposing a portion of an upper surface of each of the first electrodes by removing the second mask pattern, and etching the protective layers using the second pixel defining film as a mask.

18. The method for manufacturing the display device of claim 17, wherein in the exposing of the portion of the upper surface of each of the first electrodes, residual films formed by etching the protective films are disposed on an edge of the upper surface of the first electrodes, respectively.

19. The method for manufacturing the display device of claim 17, further comprising, forming trenches penetrating through the first pixel defining film and the second pixel defining film after the exposing of the portion of the upper surface of each of the first electrodes.

20. The method for manufacturing the display device of claim 19, further comprising, after the forming of the trenches, forming a light emitting stack covering the portion of the upper surface of each of the first electrodes and the second pixel defining film, forming a second electrode on the light emitting stack, and forming an encapsulation layer covering the second electrode.

21. A head mounted display comprising:
at least one display device;
a display device housing configured to house the at least one display device; and
an optical member configured to magnify a display image of the at least one display device, or convert an optical path,
wherein the at least one display device comprises:
a substrate;
an insulating film on the substrate;
a first electrode on the insulating film;
a residual film on an edge of an upper surface of the first electrode;
a first pixel defining film on a side surface of the first electrode and a side surface of the residual film;
a second pixel defining film on the residual film and the first pixel defining film;
a trench penetrating through the first pixel defining film and the second pixel defining film;
a light emitting stack on the upper surface of the first electrode and the second pixel defining film; and
a second electrode on the light emitting stack.
